(19) United States
(12) Patent Application Publication
(10) Pub. No.: US 2023/0299192 A1
(43) Pub. Date: Sep. 21, 2023

(54) SEMICONDUCTOR DEVICE, SEMICONDUCTOR DEVICE MANUFACTURING METHOD, INVERTER CIRCUIT, DRIVE DEVICE, VEHICLE, AND ELEVATOR

(71) Applicant: KABUSHIKI KAISHA TOSHIBA, Tokyo (JP)

(72) Inventors: Shinichi KIMOTO, Tsukuba-shi (JP); Ryosuke IIJIMA, Setagaya (JP); Shinsuke HARADA, Tssukuba-shi (JP)

(73) Assignee: KABUSHIKI KAISHA TOSHIBA, Tokyo (JP)

(21) Appl. No.: 17/823,995

(22) Filed: Sep. 1, 2022

(30) Foreign Application Priority Data
Mar. 17, 2022 (JP) 2022-042733

(51) Int. Cl. H01L 29/78; H01L 29/16; H01L 29/06; H01L 29/10; H01L 21/02; H01L 21/04; H01L 29/66

(52) U.S. Cl. CPC H01L 29/7813; H01L 29/1608; H01L 29/063; H01L 29/1095; H01L 21/02529; H01L 21/02579; H01L 21/0465; H01L 21/049; H01L 21/0485; H01L 29/66068; H02P 27/06

(57) ABSTRACT

A semiconductor device of embodiments includes: a silicon carbide layer having a first face and a second face; a trench in the silicon carbide layer extending in a first direction; a gate electrode disposed in the trench; a first silicon carbide region of n-type; a second silicon carbide region of p-type between the first silicon carbide region and the first face being shallower than the trench; a third silicon carbide region of n-type disposed between the second silicon carbide region and the first face; a fourth silicon carbide region of n-type disposed between the third silicon carbide region and the first face, a width of the fourth silicon carbide region in a second direction perpendicular to the first direction being smaller than a width of the third silicon carbide region in the second direction; and a first electrode in contact with the fourth silicon carbide region.

### CROSS-REFERENCE TO RELATED APPLICATION

This application is based upon and claims the benefit of priority from Japanese Patent Application No. 2022-042733, filed on Mar. 17, 2022, the entire contents of which are incorporated herein by reference.

### FIELD

Embodiments described herein relate generally to a semiconductor device, a semiconductor device manufacturing method, an inverter circuit, a drive device, a vehicle, and an elevator.

### BACKGROUND

Silicon carbide (SiC) is expected as a material for next-generation semiconductor devices. Silicon carbide has excellent physical properties, such as a bandgap of about 3 times that of silicon, a breakdown field strength of about times that of silicon, and a thermal conductivity of about 3 times that of silicon. By using such physical properties, it is possible to realize a semiconductor device that can operate at high temperature with low loss.

In a vertical metal oxide semiconductor field effect transistor (MOSFET) using silicon carbide, a trench gate structure in which a gate electrode is provided in a trench is applied in order to realize a low on-resistance. By applying the trench gate structure, the channel area per unit area is increased, and accordingly, the on-resistance is reduced. For the MOSFET having a trench gate structure, it is desired to realize a high threshold voltage.

### BRIEF DESCRIPTION OF THE DRAWINGS

FIG. 1 is a schematic cross-sectional view of a semiconductor device according to a first embodiment;

FIG. 2 is a schematic cross-sectional view of the semiconductor device according to the first embodiment;

FIG. 3 is an enlarged schematic cross-sectional view of the semiconductor device according to the first embodiment;

FIG. 4 is a diagram showing a profile of the n-type impurity concentration in the semiconductor device according to the first embodiment;

FIG. 5 is a schematic cross-sectional view showing an example of a method for manufacturing the semiconductor device according to the first embodiment;

FIG. 6 is a schematic cross-sectional view showing an example of the method for manufacturing the semiconductor device according to the first embodiment;

FIG. 7 is a schematic cross-sectional view showing an example of the method for manufacturing the semiconductor device according to the first embodiment;

FIG. 8 is a schematic cross-sectional view showing an example of the method for manufacturing the semiconductor device according to the first embodiment;

FIG. 9 is a schematic cross-sectional view showing an example of the method for manufacturing the semiconductor device according to the first embodiment;

FIG. 10 is a schematic cross-sectional view showing an example of the method for manufacturing the semiconductor device according to the first embodiment;

FIG. 11 is a schematic cross-sectional view showing an example of the method for manufacturing the semiconductor device according to the first embodiment;

FIG. 12 is a schematic cross-sectional view showing an example of the method for manufacturing the semiconductor device according to the first embodiment;

FIG. 13 is a schematic cross-sectional view showing an example of the method for manufacturing the semiconductor device according to the first embodiment;

FIG. 14 is a schematic cross-sectional view showing an example of the method for manufacturing the semiconductor device according to the first embodiment;

FIG. 15 is a schematic cross-sectional view showing an example of the method for manufacturing the semiconductor device according to the first embodiment;

FIG. 16 is a schematic cross-sectional view showing an example of the method for manufacturing the semiconductor device according to the first embodiment;

FIG. 17 is a schematic cross-sectional view showing an example of the method for manufacturing the semiconductor device according to the first embodiment;

FIG. 18 is a schematic cross-sectional view showing an example of the method for manufacturing the semiconductor device according to the first embodiment;

FIG. 19 is a schematic cross-sectional view showing an example of the method for manufacturing the semiconductor device according to the first embodiment;

FIG. 20 is a schematic cross-sectional view showing an example of the method for manufacturing the semiconductor device according to the first embodiment;

FIG. 21 is a schematic cross-sectional view of a semiconductor device of a modification example of the first embodiment;

FIG. 22 is a schematic cross-sectional view of a semiconductor device according to a second embodiment;

FIG. 23 is a schematic cross-sectional view of the semiconductor device according to the second embodiment;

FIG. 24 is an enlarged schematic cross-sectional view of the semiconductor device according to the second embodiment;

FIG. 25 is a schematic cross-sectional view showing an example of a method for manufacturing the semiconductor device according to the second embodiment;

FIG. 26 is a schematic cross-sectional view showing an example of the method for manufacturing the semiconductor device according to the second embodiment;

FIG. 27 is a schematic cross-sectional view showing an example of the method for manufacturing the semiconductor device according to the second embodiment;

FIG. 28 is a schematic cross-sectional view showing an example of the method for manufacturing the semiconductor device according to the second embodiment;

FIG. 29 is a schematic cross-sectional view showing an example of the method for manufacturing the semiconductor device according to the second embodiment;

FIG. 30 is a schematic cross-sectional view showing an example of the method for manufacturing the semiconductor device according to the second embodiment;

FIG. 31 is a schematic cross-sectional view showing an example of the method for manufacturing the semiconductor device according to the second embodiment;

FIG. 32 is a schematic cross-sectional view showing an example of the method for manufacturing the semiconductor device according to the second embodiment;

FIG. 33 is a schematic cross-sectional view showing an example of the method for manufacturing the semiconductor device according to the second embodiment;

FIG. 34 is a schematic cross-sectional view showing an example of the method for manufacturing the semiconductor device according to the second embodiment;

FIG. 35 is a schematic cross-sectional view showing an example of the method for manufacturing the semiconductor device according to the second embodiment;

FIG. 36 is a schematic cross-sectional view showing an example of the method for manufacturing the semiconductor device according to the second embodiment;

FIG. 37 is a schematic cross-sectional view showing an example of the method for manufacturing the semiconductor device according to the second embodiment;

FIG. 38 is a schematic cross-sectional view showing an example of the method for manufacturing the semiconductor device according to the second embodiment;

FIG. 39 is a schematic cross-sectional view showing an example of the method for manufacturing the semiconductor device according to the second embodiment;

FIG. 40 is a schematic cross-sectional view of a semiconductor device of a modification example of the second embodiment;

FIG. 41 is a schematic diagram of a drive device according to a third embodiment;

FIG. 42 is a schematic diagram of a vehicle according to a fourth embodiment;

FIG. 43 is a schematic diagram of a vehicle according to a fifth embodiment; and

FIG. 44 is a schematic diagram of an elevator according to a sixth embodiment.

### DETAILED DESCRIPTION

A semiconductor device of embodiments includes: a silicon carbide layer having a first face parallel to a first direction and a second direction perpendicular to the first direction and a second face parallel to the first face; a first trench disposed in the silicon carbide layer, disposed on a side of the first face of the silicon carbide layer, extending in the first direction, and having a first side surface and a second side surface; a first gate electrode disposed in the first trench; a first gate insulating layer disposed between the first gate electrode and the silicon carbide layer; a first silicon carbide region of n-type disposed in the silicon carbide layer; a second silicon carbide region of p-type disposed in the silicon carbide layer, disposed between the first silicon carbide region and the first face, and having a smaller depth from the first face than a depth of the first trench from the first face; a third silicon carbide region of n-type disposed in the silicon carbide layer, disposed between the second silicon carbide region and the first face, and including a first region in contact with the first side surface and a second region in contact with the second side surface, a width of the third silicon carbide region in the second direction being a first width; a fourth silicon carbide region of n-type disposed in the silicon carbide layer, disposed between the third silicon carbide region and the first face, and including a third region in contact with the first side surface and the first region and a fourth region in contact with the second side surface and the second region, a width of the fourth silicon carbide region in the second direction being a second width smaller than the first width; a first electrode disposed on the side of the first face with respect to the silicon carbide layer and in contact with the fourth silicon carbide region; a second electrode disposed on a side of the second face with respect to the silicon carbide layer; and an interlayer insulating layer provided between the first gate electrode and the first electrode.

Hereinafter, embodiments will be described with reference to the diagrams. In the following description, the same or similar members and the like will be denoted by the same reference numerals, and the description of the members and the like once described will be omitted as appropriate.

In addition, in the following description, when the notations of n⁺, n, n⁻, p⁺, p, and p⁻ are used, these notations indicate the relative high and low of the impurity concentration in each conductive type. That is, n⁺ indicates that the n-type impurity concentration is relatively higher than n, and n⁻ indicates that the n-type impurity concentration is relatively lower than n. In addition, indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, the distance such as the width or depth of an impurity region can be calculated by, for example, SIMS. In addition, the distance such as the width or depth of an impurity region can be calculated from, for example, an SCM image.

The width of a trench, the distance between trenches, the depth of a trench, the thickness of an insulating layer, and the like can be measured, for example, on an image of transmission electron microscope (TEM).

In this specification, the impurity concentration in a specific region is represented by the impurity concentration in the central portion of the corresponding region, unless otherwise defined.

### First Embodiment

A semiconductor device according to a first embodiment includes: a silicon carbide layer having a first face parallel to a first direction and a second direction perpendicular to the first direction and a second face parallel to the first face; a first trench disposed in the silicon carbide layer, disposed on a side of the first face of the silicon carbide layer, extending in the first direction, and having a first side surface and a second side surface; a first gate electrode disposed in the first trench; a first gate insulating layer disposed between the first gate electrode and the silicon carbide layer; a first silicon carbide region of n-type disposed in the silicon carbide layer; a second silicon carbide region of p-type disposed in the silicon carbide layer, disposed between the first silicon carbide region and the first face, and having a smaller depth from the first face than a depth of the first trench from the first face; a third silicon carbide region of n-type disposed in the silicon carbide layer, disposed between the second silicon carbide region and the first face, and including a first region in contact with the first side surface and a second region in contact with the second side surface, a width of the third silicon carbide region in the second direction being a first width; a fourth silicon carbide region of n-type disposed in the silicon carbide layer, disposed between the third silicon carbide region and the first face, and including a third region in contact with the first side surface and the first region and a fourth region in contact with the second side surface and the second region, a width of the fourth silicon carbide region in the second direction being a second width smaller than the first width; a first electrode disposed on the side of the first face with respect to the silicon carbide layer and in contact with the fourth silicon carbide region; a second electrode disposed on a side of the second face with respect to the silicon carbide layer; and an interlayer insulating layer provided between the first gate electrode and the first electrode.

In addition, the semiconductor device according to the first embodiment further includes: a second trench disposed in the silicon carbide layer, disposed on the side of the first face of the silicon carbide layer, extending in the first direction, disposed in the second direction with respect to the first trench, and having a third side surface facing the second side surface and a fourth side surface; a second gate electrode disposed in the second trench; a second gate insulating layer disposed between the second gate electrode and the silicon carbide layer; a fifth silicon carbide region of n-type disposed in the silicon carbide layer, disposed between the second silicon carbide region and the first face, and including a fifth region in contact with the third side surface and a sixth region in contact with the fourth side surface, a width of the fifth silicon carbide region in the second direction being a third width; and a sixth silicon carbide region of n-type disposed in the silicon carbide layer, disposed between the fifth silicon carbide region and the first face, and including a seventh region in contact with the third side surface and the fifth region and an eighth region in contact with the fourth side surface and the sixth region, a width of the sixth silicon carbide region in the second direction being a fourth width smaller than the third width. In addition, the second silicon carbide region is disposed between the third silicon carbide region and the fifth silicon carbide region.

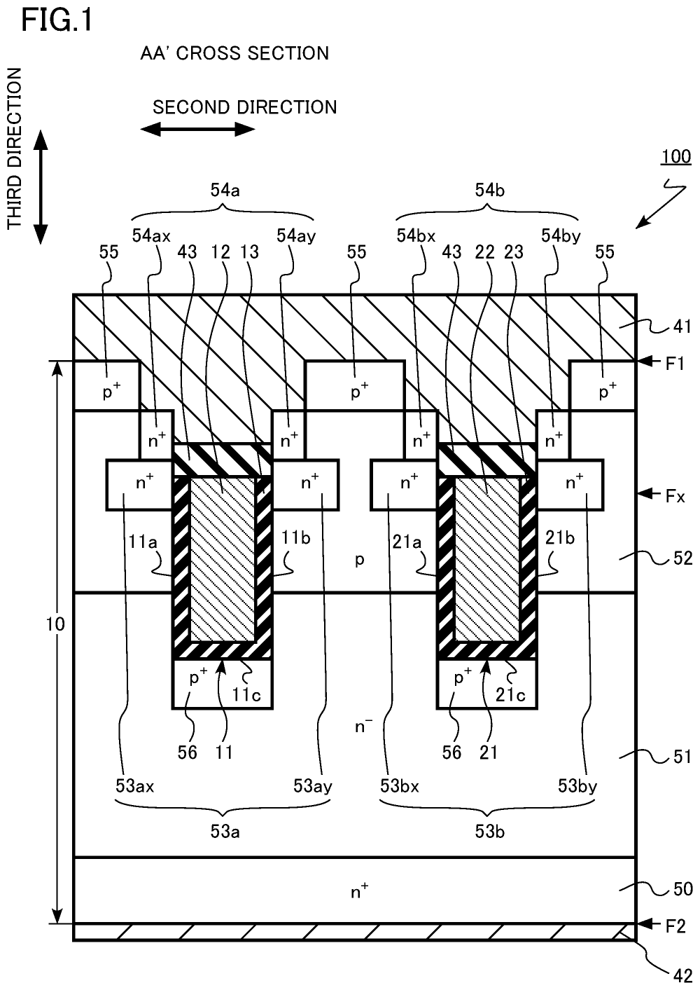

FIG. 1 is a schematic cross-sectional view of the semiconductor device according to the first embodiment. The semiconductor device according to the first embodiment is a trench gate type vertical MOSFET 100 using silicon carbide. The MOSFET 100 is an n-channel MOSFET having electrons as carriers.

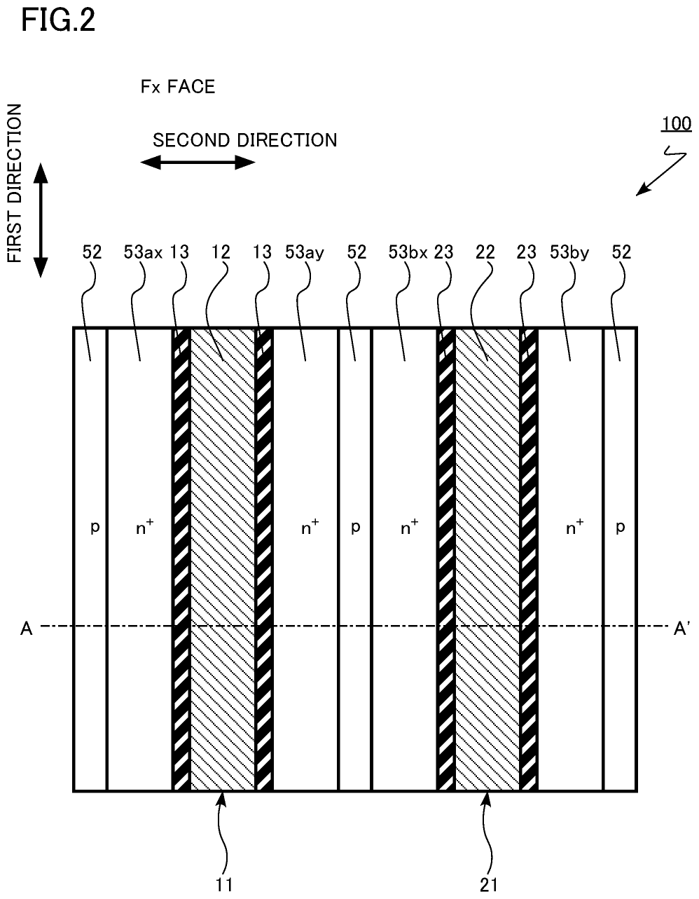

FIG. 2 is a schematic cross-sectional view of the semiconductor device according to the first embodiment. FIG. 2 is a cross-sectional view taken along the Fx face of FIG. 1. FIG. 1 is a cross-sectional view taken along the line AA′ of FIG. 2.

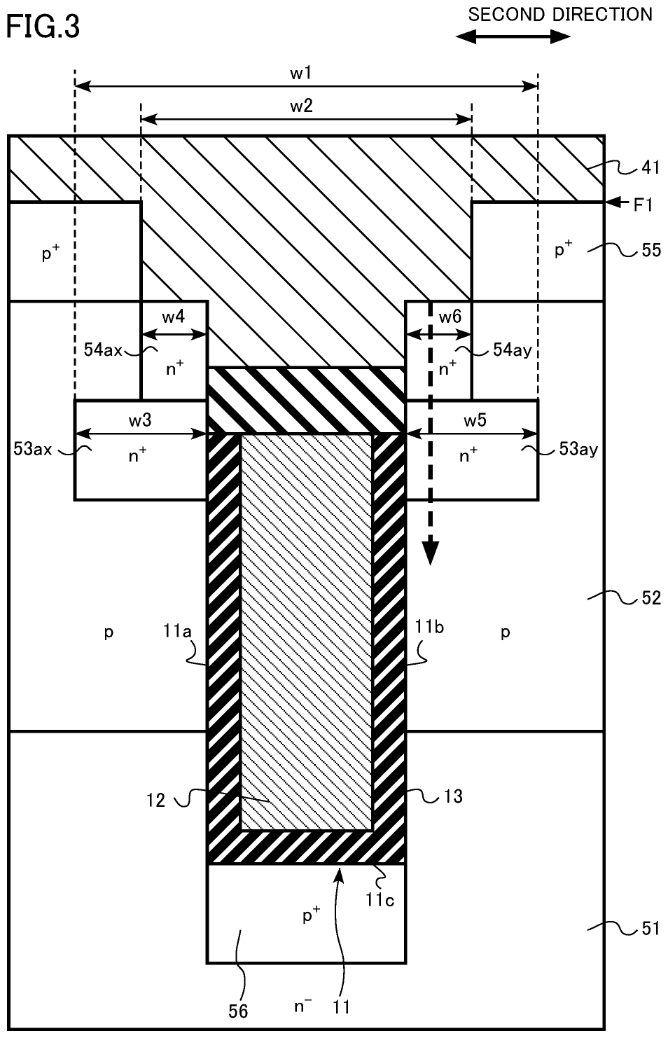

FIG. 3 is an enlarged schematic cross-sectional view of the semiconductor device according to the first embodiment. FIG. 3 is an enlarged view of a part of FIG. 1.

A MOSFET 100 includes a silicon carbide layer 10, a first trench 11, a first gate electrode 12, a first gate insulating layer 13, a second trench 21, a second gate electrode 22, a second gate insulating layer 23, a source electrode 41 (first electrode), a drain electrode 42 (second electrode), and an interlayer insulating layer 43.

Hereinafter, the first trench 11 and the second trench 21 may be collectively referred to as a trench. In addition, the first gate electrode 12 and the second gate electrode 22 may be collectively referred to as a gate electrode. In addition, the first gate insulating layer 13 and the second gate insulating layer 23 may be collectively referred to as a gate insulating layer.

In the silicon carbide layer 10, an n⁺-type drain region 50, an n⁻-type drift region 51 (first silicon carbide region), a p-type body region 52 (second silicon carbide region), a first lower source region 53a of n⁺-type (third silicon carbide region), a second lower source region 53b of n⁺-type (fifth silicon carbide region), a first upper source region 54a of n⁺-type (fourth silicon carbide region), a second upper source region 54b of n⁺-type (sixth silicon carbide region), a p⁺-type contact region 55 (seventh silicon carbide region), and a p⁺-type electric field relaxation region 56 are provided.

Hereinafter, the first lower source region 53a and the second lower source region 53b may be collectively referred to as a lower source region 53. In addition, the first upper source region 54a and the second upper source region 54b may be collectively referred to as an upper source region 54.

The silicon carbide layer 10 is a single crystal SiC. The silicon carbide layer 10 is, for example, 4H—SiC.

The silicon carbide layer 10 includes a first face (“F1” in FIG. 1) and a second face (“F2” in FIG. 1). The first face F1 and the second face F2 face each other. The first face F1 and the second face F2 are parallel to each other. Hereinafter, the first face F1 is also referred to as a surface, and the second face F2 is also referred to as a back surface. Hereinafter, the “depth” means a depth in a direction toward the second face F2 with the first face F1 as a reference.

In FIGS. 1 to 3, the first direction and the second direction are directions parallel to the first face F1. In addition, the second direction is a direction perpendicular to the first direction.

In FIGS. 1 to 3, the third direction is a direction perpendicular to the first direction and the second direction. The third direction is a direction from the first face F1 to the second face F2. Hereinafter, the third direction may be referred to as a depth direction.

The first face F1 is, for example, a face inclined by an angle equal to or more than 0° and equal to or less than 8° with respect to the (0001) face. That is, the first face F1 is a face whose normal is inclined by an angle equal to or more than 0° and equal to or less than 8° with respect to the c axis in the [0001] direction. In other words, an off angle with respect to the (0001) face is equal to or more than 0° and equal to or less than 8°. In addition, the second face F2 is, for example, a face inclined by an angle equal to or more than 0° and equal to or less than 8° with respect to the (000-1) face.

The (0001) face is referred to as a silicon face. The (000-1) face is referred to as a carbon face. The inclination direction of the first face F1 and the second face F2 is, for example, a [11-20] direction. The [11-20] direction is an a-axis direction. In FIG. 1, for example, the second direction shown in the diagram is the a-axis direction.

The first trench 11 and the second trench 21 are disposed in the silicon carbide layer 10. The first trench 11 and the second trench 21 are disposed on the surface side of the silicon carbide layer 10. The first trench 11 and the second trench 21 extend in the first direction as shown in FIG. 2.

The widths of the first trench 11 and the second trench 21 in the second direction are smaller than, for example, the distance between the first trench 11 and the second trench 21.

The widths of the first trench 11 and the second trench 21 in the second direction are, for example, equal to or more than 0.3 μm and equal to or less than 1 μm. The distance between the first trench 11 and the second trench 21 is, for example, equal to or more than 0.5 μm and equal to or less than 2 μm. The depths of the first trench 11 and the second trench 21 are, for example, equal to or more than 1 μm and equal to or less than 3 μm.

A plurality of trenches including the first trench 11 and the second trench 21 are repeatedly arranged in the second direction. The repetition pitch of the plurality of trenches in the second direction is, for example, equal to or more than 1 μm and equal to or less than 5 μm.

The first trench 11 has a first side surface 11a, a second side surface 11b, and a first bottom surface 11c. The first bottom surface 11c is provided between the first side surface 11a and the second side surface 11b.

The first gate electrode 12 is provided in the first trench 11. The first gate electrode 12 is provided between the source electrode 41 and the drain electrode 42. The first gate electrode 12 extends in the first direction.

The first gate insulating layer 13 is provided between the first gate electrode 12 and the silicon carbide layer 10. The first gate insulating layer 13 is provided between the first gate electrode 12 and each of the first lower source region 53a, the body region 52, the drift region 51, and the electric field relaxation region 56.

The second trench 21 has a third side surface 21a, a fourth side surface 21b, and a second bottom surface 21c. The second bottom surface 21c is provided between the third side surface 21a and the fourth side surface 21b. The third side surface 21a faces the second side surface 11b.

The second gate electrode 22 is provided in the second trench 21. The second gate electrode 22 is provided between the source electrode 41 and the drain electrode 42. The second gate electrode 22 extends in the first direction.

The second gate insulating layer 23 is provided between the second gate electrode 22 and the silicon carbide layer 10. The second gate insulating layer 23 is provided between the second gate electrode 22 and each of the second lower source region 53b, the body region 52, the drift region 51, and the electric field relaxation region 56.

The first gate electrode 12 and the second gate electrode 22 are conductive layers. The first gate electrode 12 and the second gate electrode 22 are, for example, polycrystalline silicon containing p-type impurities or n-type impurities.

The first gate insulating layer 13 and the second gate insulating layer 23 are, for example, silicon oxide films. For example, a High-k insulating film (high dielectric constant insulating film, such as HfSiON, ZrSiON, and AlON) can be applied to the first gate insulating layer 13 and the second gate insulating layer 23. In addition, for example, a stacked film of a silicon oxide film (SiO₂) and a High-k insulating film can also be applied to the first gate insulating layer 13 and the second gate insulating layer 23.

The interlayer insulating layer 43 is provided on the first gate electrode 12 and on the second gate electrode 22. The interlayer insulating layer 43 is provided between the first gate electrode 12 and the source electrode 41 and between the second gate electrode 22 and the source electrode 41.

At least a part of the interface between the interlayer insulating layer 43 and the source electrode 41 is disposed in the first trench 11. At least a part of the interface between the interlayer insulating layer 43 and the source electrode 41 is disposed in the second trench 21.

The interlayer insulating layer 43 is, for example, a silicon oxide film.

The source electrode 41 is provided on the surface side of the silicon carbide layer 10. The source electrode 41 is provided on the surface of the silicon carbide layer 10. The source electrode 41 is electrically connected to the body region 52, the upper source region 54, the lower source region 53, and the contact region 55. The source electrode 41 is in contact with the upper source region 54 and the contact region 55.

The source electrode 41 is in contact with a first side surface 11a and a second side surface 11b of the first trench 11. The source electrode 41 is in contact with a third region 54ax of the first upper source region 54a on the first side surface 11a. The source electrode 41 is in contact with a fourth region 54ay of the first upper source region 54a on the second side surface 11b.

The source electrode 41 is in contact with a third side surface 21a and a fourth side surface 21b of the second trench 21. The source electrode 41 is in contact with a seventh region 54bx of the second upper source region 54b on the third side surface 21a. The source electrode 41 is in contact with an eighth region 54by of the second upper source region 54b on the fourth side surface 21b.

The source electrode 41 contains metal. The metal forming the source electrode 41 is, for example, a stacked structure of titanium (Ti) and aluminum (Al). The source electrode 41 may contain a metal silicide or a metal carbide in contact with the silicon carbide layer 10.

The drain electrode 42 is provided on the back surface side of the silicon carbide layer 10. The drain electrode 42 is provided on the back surface of the silicon carbide layer 10. The drain electrode 42 is in contact with the drain region 50.

The drain electrode 42 is, for example, a metal or a metal semiconductor compound. The drain electrode 42 contains a material selected from a group consisting of nickel silicide (NiSi), titanium (Ti), nickel (Ni), silver (Ag), and gold (Au), for example.

The n⁺-type drain region 50 is provided on the back surface side of the silicon carbide layer 10. The drain region 50 contains, for example, nitrogen (N) as an n-type impurity. The n-type impurity concentration in the drain region 50 is, for example, equal to or more than 1×10¹⁸ cm⁻³ and equal to or less than 1×10²¹ cm⁻³.

The n⁻-type drift region 51 is provided on the drain region 50. The drift region 51 is provided between the drain region 50 and the surface of the silicon carbide layer 10.

The drift region 51 contains, for example, nitrogen (N) as an n-type impurity. The n-type impurity concentration in the drift region 51 is, for example, equal to or more than 4×10¹⁴ cm⁻³ and equal to or less than 1×10¹⁸ cm⁻³. The thickness of the drift region 51 in the third direction is, for example, equal to or more than 4 μm and equal to or less than 150 μm.

The p-type body region 52 is provided between the drift region 51 and the surface of the silicon carbide layer 10. The body region 52 is provided between the first trench 11 and the second trench 21. The body region 52 is in contact with the first side surface 11a, the second side surface 11b, the third side surface 21a, and the fourth side surface 21b.

The body region 52 functions as a channel region of the MOSFET 100. For example, when the MOSFET 100 is turned on, a channel through which electrons flow is formed in a region of the body region 52 in contact with the gate insulating layer.

The depth of the body region 52 is larger than the depth of the first trench 11 from the surface of the silicon carbide layer 10. The first trench 11 penetrates the body region 52. The depth of the body region 52 is larger than the depth of the second trench 21 from the surface of the silicon carbide layer 10. The second trench 21 penetrates the body region 52. The depth of the body region 52 is, for example, equal to or more than 0.8 μm and equal to or less than 2.0 μm.

The body region 52 contains, for example, aluminum (Al) as a p-type impurity. The p-type impurity concentration in the body region 52 is, for example, equal to or more than 5×10¹⁶ cm⁻³ and equal to or less than 5×10¹⁸ cm⁻³.

The first lower source region 53a of n⁺-type is provided between the body region 52 and the surface of the silicon carbide layer 10. The first lower source region 53a extends in the first direction.

The first lower source region 53a includes a first region 53ax and a second region 53ay. The first trench 11 is disposed between the first region 53ax and the second region 53ay. The second region 53ay is disposed in the second direction of the first region 53ax.

The first region 53ax is in contact with the first side surface 11a of the first trench 11. The second region 53ay is in contact with the second side surface 11b of the first trench 11.

The first lower source region 53a contains nitrogen (N) or phosphorus (P) as an n-type impurity. The n-type impurity concentration in the first lower source region 53a is, for example, equal to or more than 1×10¹⁹ cm⁻³ and equal to or less than 1×10²¹ cm⁻³.

The depth of the first lower source region 53a is smaller than the depth of the body region 52. The depth of the first lower source region 53a is, for example, equal to or more than 0.4 μm and equal to or less than 1.0 μm. The distance between the drift region 51 and the first lower source region 53a is, for example, equal to or more than 0.1 μm and equal to or less than 0.9 μm.

The second lower source region 53b of n⁺-type is provided between the body region 52 and the surface of the silicon carbide layer 10. The second lower source region 53b extends in the first direction.

The second lower source region 53b is provided in the second direction of the first lower source region 53a. The body region 52 is disposed between the first lower source region 53a and the second lower source region 53b.

The second lower source region 53b includes a fifth region 53bx and a sixth region 53by. The second trench 21 is disposed between the fifth region 53bx and the sixth region 53by. The sixth region 53by is disposed in the second direction of the fifth region 53bx.

The fifth region 53bx is in contact with the third side surface 21a of the second trench 21. The sixth region 53by is in contact with the fourth side surface 21b of the second trench 21.

The second lower source region 53b contains nitrogen (N) or phosphorus (P) as an n-type impurity. The n-type impurity concentration in the second lower source region 53b is, for example, equal to or more than 1×10¹⁹ cm⁻³ and equal to or less than 1×10²¹ cm⁻³.

The depth of the second lower source region 53b is smaller than the depth of the body region 52. The depth of the second lower source region 53b is, for example, equal to or more than 0.1 μm and equal to or less than 0.3 μm. The distance between the drift region 51 and the second lower source region 53b is, for example, equal to or more than 0.1 μm and equal to or less than 0.9 μm.

The first upper source region 54a of n⁺-type is provided between the first lower source region 53a and the surface of the silicon carbide layer 10. The first upper source region 54a extends in the first direction.

The first upper source region 54a includes the third region 54ax and the fourth region 54ay. The first trench 11 is disposed between the third region 54ax and the fourth region 54ay. The fourth region 54ay is disposed in the second direction of the third region 54ax.

The third region 54ax is in contact with the first side surface 11a of the first trench 11. The third region 54ax is in contact with the first region 53ax. The fourth region 54ay is in contact with the second side surface 11b of the first trench 11. The fourth region 54ay is in contact with the second region 53ay.

The first upper source region 54a is in contact with the source electrode 41. The first upper source region 54a is in contact with the source electrode 41 on the side surface of the first trench 11.

The third region 54ax is in contact with the source electrode 41 on the first side surface 11a of the first trench 11. The fourth region 54ay is in contact with the source electrode 41 on the second side surface 11b of the first trench 11.

The first upper source region 54a contains nitrogen (N) or phosphorus (P) as an n-type impurity. The n-type impurity concentration in the first upper source region 54a is, for example, equal to or more than 1×10¹⁹ cm⁻³ and equal to or less than 1×10²¹ cm⁻³.

The second upper source region 54b of n⁺-type is provided between the second lower source region 53b and the surface of the silicon carbide layer 10. The second upper source region 54b extends in the first direction.

The second upper source region 54b includes the seventh region 54bx and the eighth region 54by. The second trench 21 is disposed between the seventh region 54bx and the eighth region 54by. The eighth region 54by is disposed in the second direction of the seventh region 54bx.

The seventh region 54bx is in contact with the third side surface 21a of the second trench 21. The seventh region 54bx is in contact with the fifth region 53bx. The eighth region 54by is in contact with the fourth side surface 21b of the second trench 21. The eighth region 54by is in contact with the sixth region 53by.

The second upper source region 54b is in contact with the source electrode 41. The second upper source region 54b is in contact with the source electrode 41 on the side surface of the second trench 21.

The seventh region 54bx is in contact with the source electrode 41 on the third side surface 21a of the second trench 21. The eighth region 54by is in contact with the source electrode 41 on the fourth side surface 21b of the second trench 21.

The second upper source region 54b contains nitrogen (N) or phosphorus (P) as an n-type impurity. The n-type impurity concentration in the second upper source region 54b is, for example, equal to or more than 1×10¹⁹ cm⁻³ and equal to or less than 1×10²¹ cm⁻³.

The second upper source region 54b is provided in the second direction of the first upper source region 54a. The body region 52 is disposed between the first upper source region 54a and the second upper source region 54b.

The second width (w2 in FIG. 3) of the first upper source region 54a in the second direction is smaller than the first width (w1 in FIG. 3) of the first lower source region 53a in the second direction. In other words, the first width (w1 in FIG. 3) of the first lower source region 53a in the second direction is larger than the second width (w2 in FIG. 3) of the first upper source region 54a in the second direction. The difference between the first width (w1 in FIG. 3) of the first lower source region 53a and the second width (w2 in FIG. 3) of the first upper source region 54a in the second direction is, for example, equal to or more than 0.1 μm.

The width (w4 in FIG. 3) of the third region 54ax in the second direction is smaller than, for example, the width (w3 in FIG. 3) of the first region 53ax in the second direction. In other words, the width (w3 in FIG. 3) of the first region 53ax in the second direction is larger than, for example, the width (w4 in FIG. 3) of the third region 54ax in the second direction.

In addition, the width (w6 in FIG. 3) of the fourth region 54ay in the second direction is smaller than, for example, the width (w5 in FIG. 3) of the second region 53ay in the second direction. In other words, the width (w5 in FIG. 3) of the second region 53ay in the second direction is larger than, for example, the width (w6 in FIG. 3) of the fourth region 54ay in the second direction.

The fourth width of the second upper source region 54b in the second direction is smaller than the third width of the second lower source region 53b in the second direction. In other words, the third width of the second lower source region 53b in the second direction is larger than the fourth width of the second upper source region 54b in the second direction. The difference between the third width of the second lower source region 53b in the second direction and the fourth width of the second upper source region 54b in the second direction is, for example, equal to or more than 0.1 μm.

The width of the seventh region 54bx in the second direction is smaller than, for example, the width of the fifth region 53bx in the second direction. In addition, the width of the eighth region 54by in the second direction is smaller than the width of the sixth region 53by in the second direction.

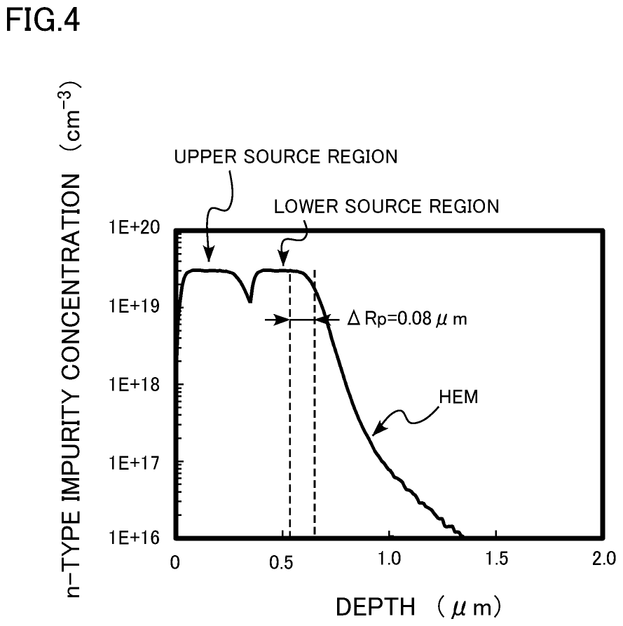

FIG. 4 is a diagram showing a profile of the n-type impurity concentration in the semiconductor device according to the first embodiment. FIG. 4 is an n-type impurity profile of a portion of the silicon carbide layer including the upper source region 54, the lower source region 53, and the body region 52 in a direction from the first face F1 to the second face F2. Specifically, FIG. 4 is an n-type impurity profile in a portion indicated by the dotted arrow in FIG. 3.

For example, in the MOSFET 100, as shown in FIG. 4, in the n-type impurity profile, the standard deviation (ΔRp) of the profile of the hem on the body region 52 side is equal to or less than 0.08 μm. The standard deviation (ΔRp) of the profile of the hem on the body region 52 side can be calculated by fitting the profile of the hem to the Pearson distribution.

The p⁺-type contact region 55 is provided between the body region 52 and the surface of the silicon carbide layer 10. The contact region 55 is in contact with the source electrode 41.

The contact region 55 contains, for example, aluminum (Al) as a p-type impurity. The p-type impurity concentration in the contact region 55 is, for example, higher than the p-type impurity concentration in the body region 52.

The p-type impurity concentration in the contact region 55 is, for example, equal to or more than 1×10¹⁸ cm⁻³ and equal to or less than 1×10²¹ cm⁻³. In addition, the p-type impurity concentration in a portion of the contact region 55 in contact with the source electrode 41 is, for example, equal to or more than 1×10¹⁹ cm⁻³ and equal to or less than 1×10²¹ cm⁻³.

The p⁺-type electric field relaxation region 56 is provided between the drift region 51 and the first trench 11. The electric field relaxation region 56 is provided between the drift region 51 and the first bottom surface 11c. The electric field relaxation region 56 is in contact with the first bottom surface 11c.

The electric field relaxation region 56 is provided between the drift region 51 and the second trench 21. The electric field relaxation region 56 is provided between the drift region 51 and the second bottom surface 21c. The electric field relaxation region 56 is in contact with the second bottom surface 21c.

The electric field relaxation region 56 contains, for example, aluminum (Al) as a p-type impurity. The p-type impurity concentration in the electric field relaxation region 56 is, for example, higher than the p-type impurity concentration in the body region 52. The p-type impurity concentration in the electric field relaxation region 56 is, for example, equal to or more than 1×10¹⁷ cm⁻³ and equal to or less than 1×10²⁰ cm⁻³.

The electric potential of the electric field relaxation region 56 is fixed to, for example, the electric potential of the source electrode 41. The electric potential of the electric field relaxation region 56 is fixed to, for example, the source electric potential. The electric field relaxation region 56 has a function of relaxing the electric field applied to the gate insulating layer at the bottom of the trench.

A method for manufacturing the semiconductor device according to the first embodiment includes: forming a first region of p-type by ion-implanting p-type impurities into a first silicon carbide layer of n-type; forming, on the first silicon carbide layer, a first mask material having a first opening where the first region is exposed; forming a second region of n-type having a smaller depth than the first region by ion-implanting n-type impurities into the first region through the first opening using the first mask material as a mask; removing the first mask material; forming a second silicon carbide layer of p-type on the first silicon carbide layer by using an epitaxial growth method; forming, on the second silicon carbide layer, a second mask material having a second opening where the second silicon carbide layer above the second region is exposed; forming a third region of n-type in contact with the second region by ion-implanting n-type impurities into the second silicon carbide layer through the second opening using the second mask material as a mask; forming a sidewall in the second opening; forming a trench penetrating the third region, the second region, and the first region using the second mask material and the sidewall as a mask; forming a gate insulating layer in the trench; and forming a gate electrode on the gate insulating layer in the trench so that an upper surface of the gate electrode is disposed in the trench.

Next, an example of the method for manufacturing the semiconductor device according to the first embodiment will be described.

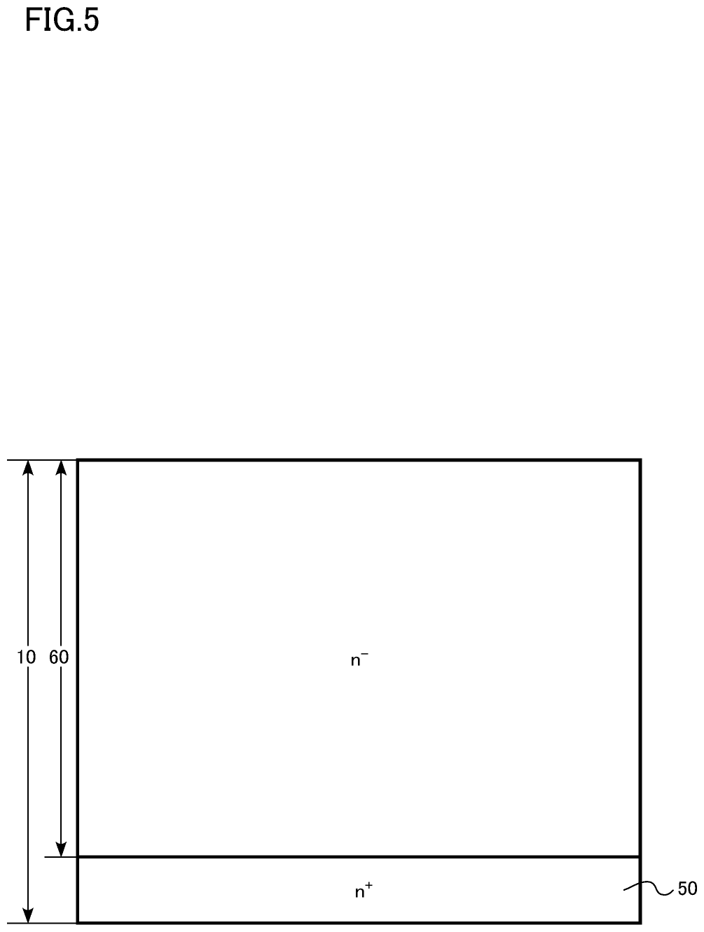

FIGS. 5 to 20 are schematic cross-sectional views showing an example of the method for manufacturing the semiconductor device according to the first embodiment. FIGS. 5 to 20 are cross-sectional views corresponding to FIG. 1.

First, the silicon carbide layer 10 having an n⁺-type drain region 50 and a first epitaxial layer 60 of n⁻-type formed on the drain region 50 by using an epitaxial growth method is prepared (FIG. 5). The first epitaxial layer 60 is an example of the first silicon carbide layer. A part of the first epitaxial layer 60 finally becomes the drift region 51.

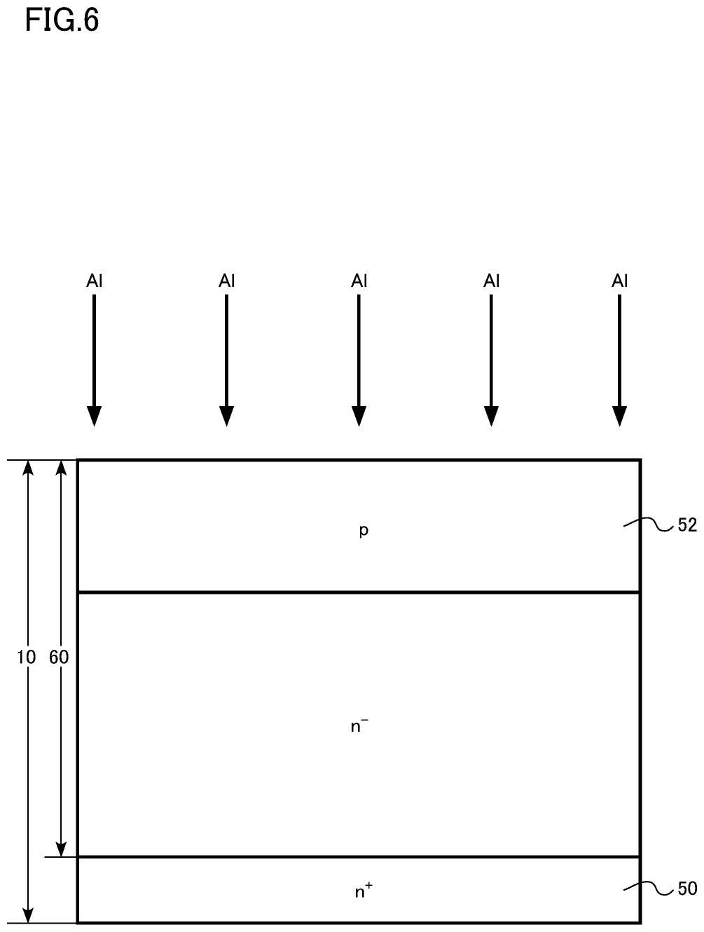

Then, p-type impurities are ion-implanted into the first epitaxial layer 60 to form the p-type body region 52 (FIG. 6). The body region 52 is an example of the first region. The p-type impurity is, for example, aluminum (Al). It is also possible to form the body region 52 by using the epitaxial growth method.

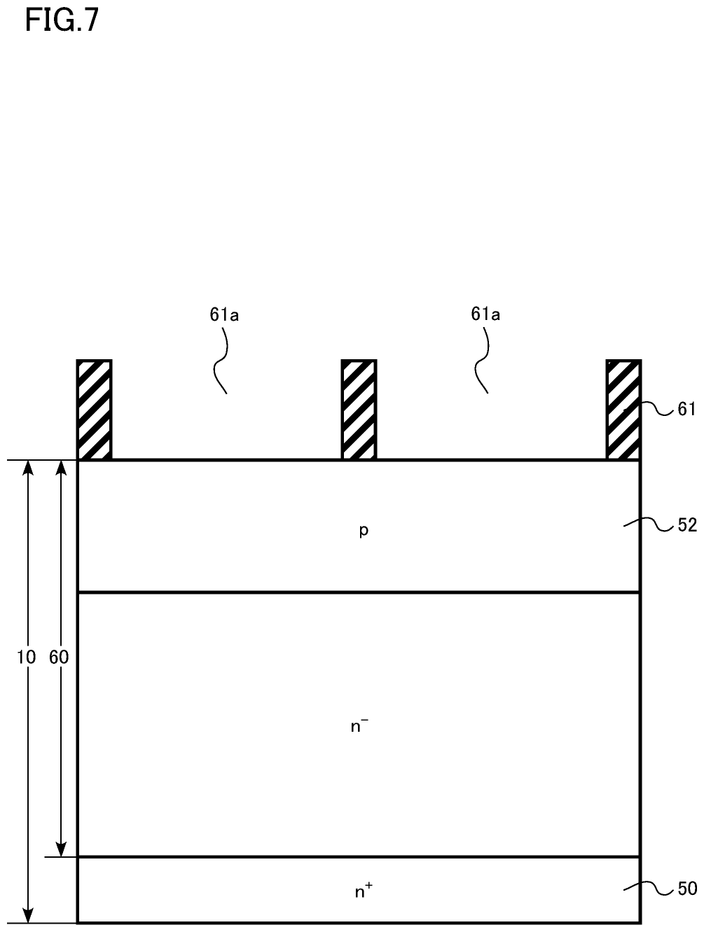

Then, a first mask material 61 is formed on the first epitaxial layer 60 (FIG. 7). The first mask material 61 has a first opening 61a. At the first opening 61a, the body region 52 is exposed.

The first mask material 61 is formed, for example, by depositing a film by using a chemical vapor deposition method (CVD method) and patterning the film by using a lithography method and a reactive ion etching method (RIE method). The first mask material 61 is, for example, a silicon oxide film.

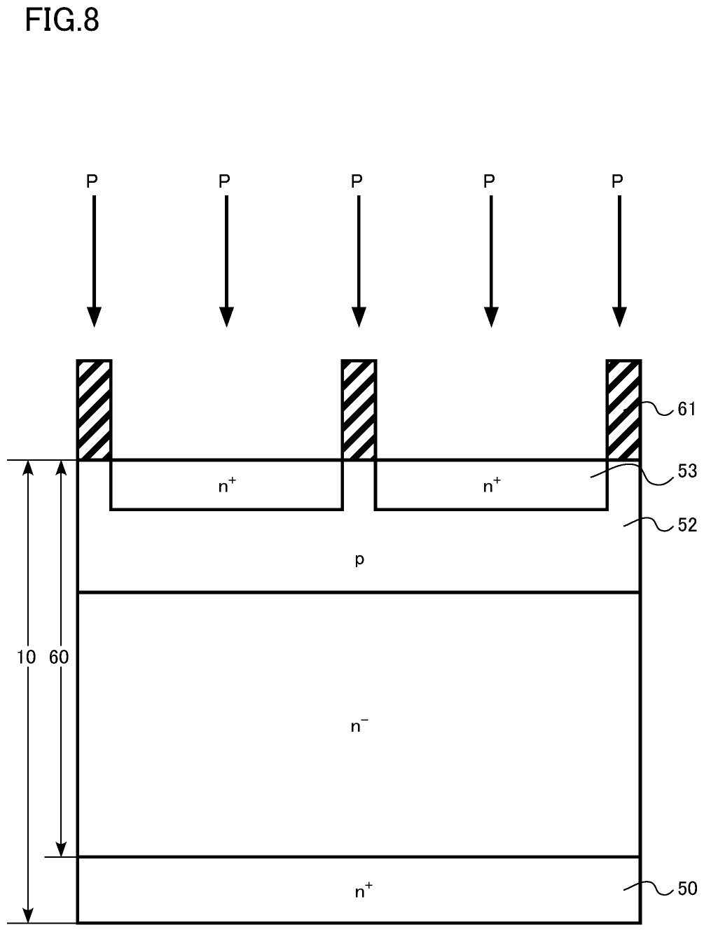

Then, by using the first mask material 61 as a mask, n-type impurities are ion-implanted into the body region 52 through the first opening 61a to form the n⁺-type lower source region 53 (FIG. 8). The lower source region 53 is an example of the second region. The lower source region 53 is shallower than the body region 52. The n-type impurity is, for example, phosphorus (P) or nitrogen (N).

When the n-type impurity to be ion-implanted when forming the lower source region 53 is phosphorus (P), the ion implantation is performed with an accelerating voltage equal to or more than 100 keV and equal to or less than 350 keV, for example. In addition, when the n-type impurity to be ion-implanted is nitrogen (N), the ion implantation is performed with an accelerating voltage equal to or more than 100 keV and equal to or less than 450 keV, for example.

Then, the first mask material 61 is removed. The first mask material 61 is removed by using, for example, a wet etching method.

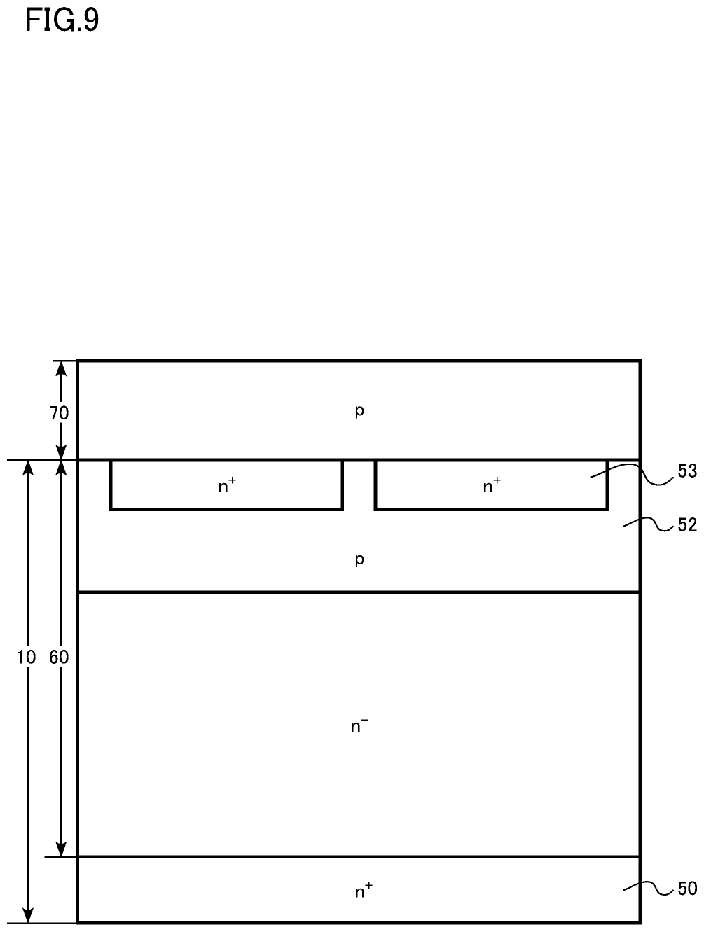

Then, a second epitaxial layer 70 of p-type is formed on the first epitaxial layer 60 by using an epitaxial growth method (FIG. 9). The second epitaxial layer 70 is an example of the second silicon carbide layer. For example, it is also possible to form a second epitaxial layer of p-type by forming an n-type epitaxial layer by using an epitaxial growth method and then ion-implanting p-type impurities.

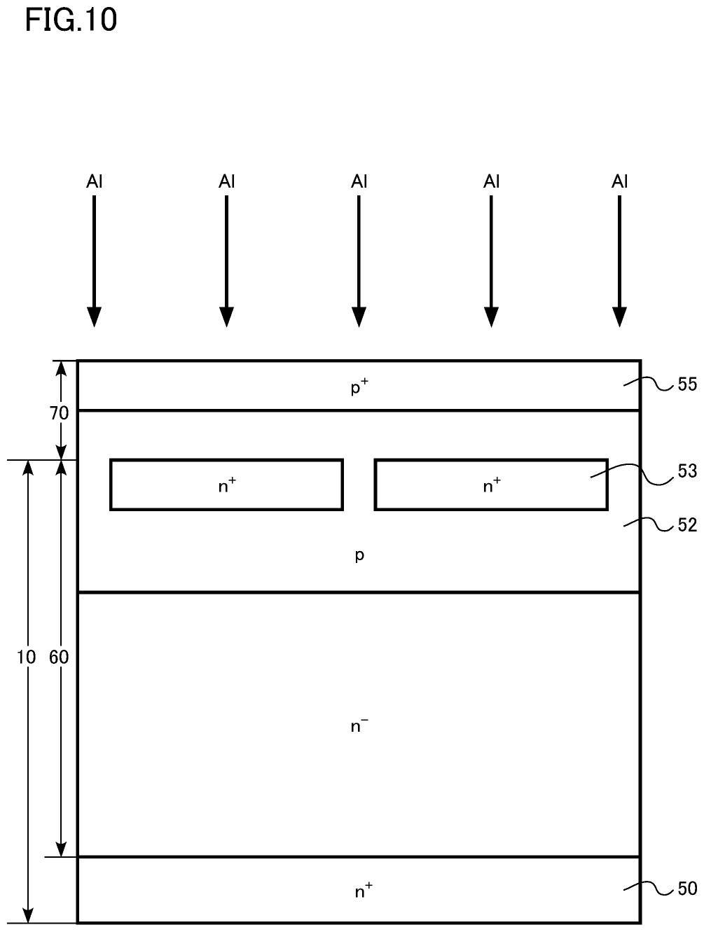

Then, p-type impurities are ion-implanted into the second epitaxial layer 70 to form the p⁺-type contact region 55 (FIG. 10). The contact region 55 is an example of the fourth region. The p-type impurity is, for example, aluminum (Al).

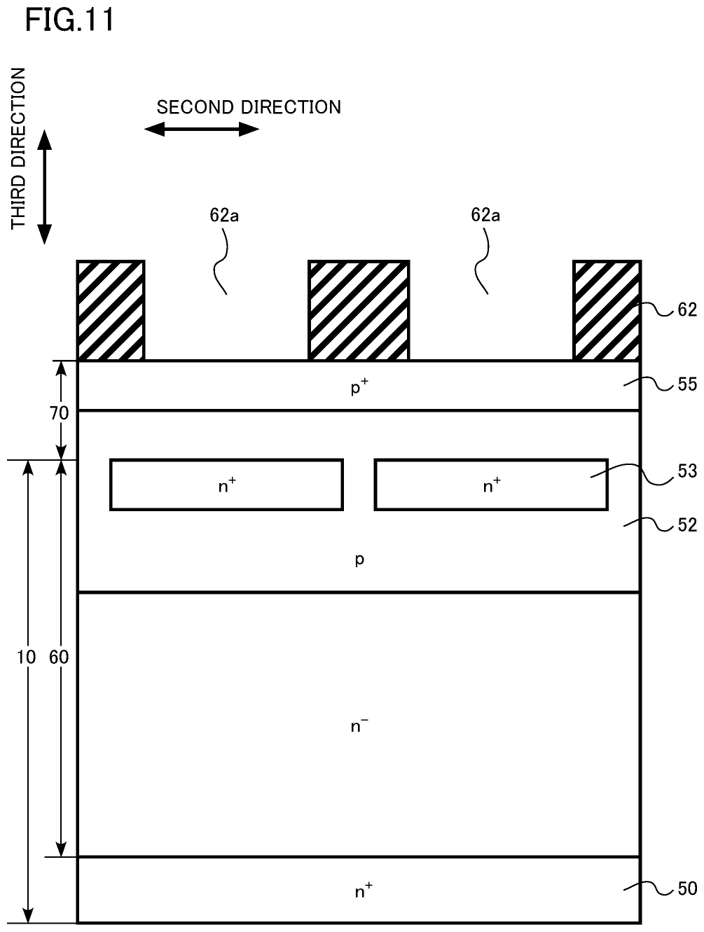

Then, a second mask material 62 is formed on the second epitaxial layer 70 (FIG. 11). The second mask material 62 has a second opening 62a. At the second opening 62a, the second epitaxial layer 70 above the lower source region 53 is exposed. The width of the second opening 62a in the second direction is smaller than the width of the lower source region 53 in the second direction.

For example, the second mask material 62 is formed by depositing a film by using a CVD method and patterning the film by using a lithography method and an RIE method. The second mask material 62 is, for example, a silicon oxide film.

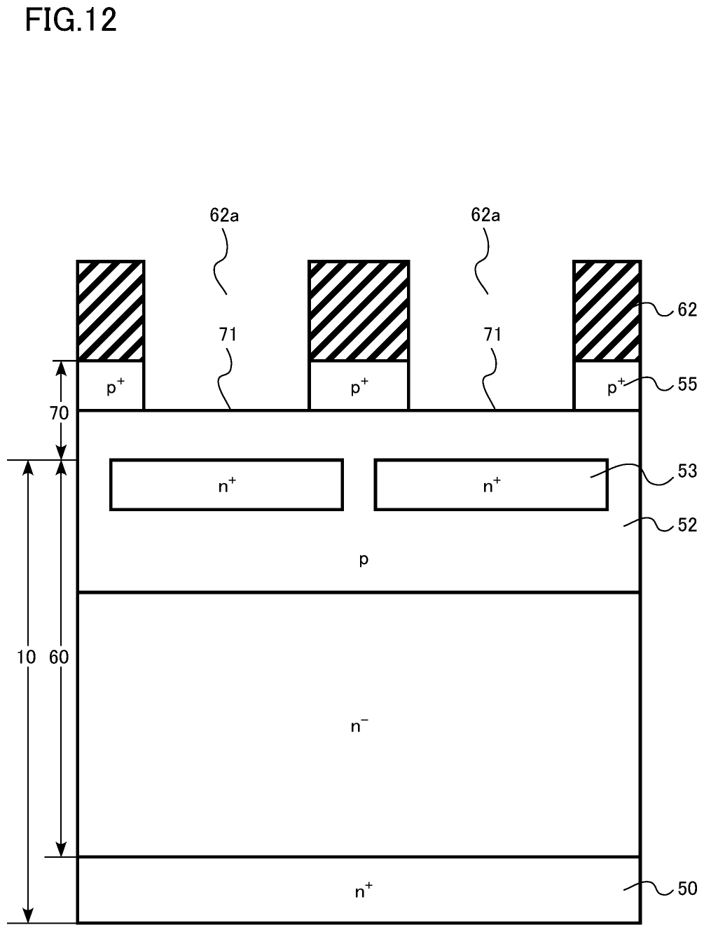

Then, by using the second mask material 62 as a mask, a recess 71 penetrating the contact region 55 is formed (FIG. 12). The recess 71 is formed by using, for example, an RIE method.

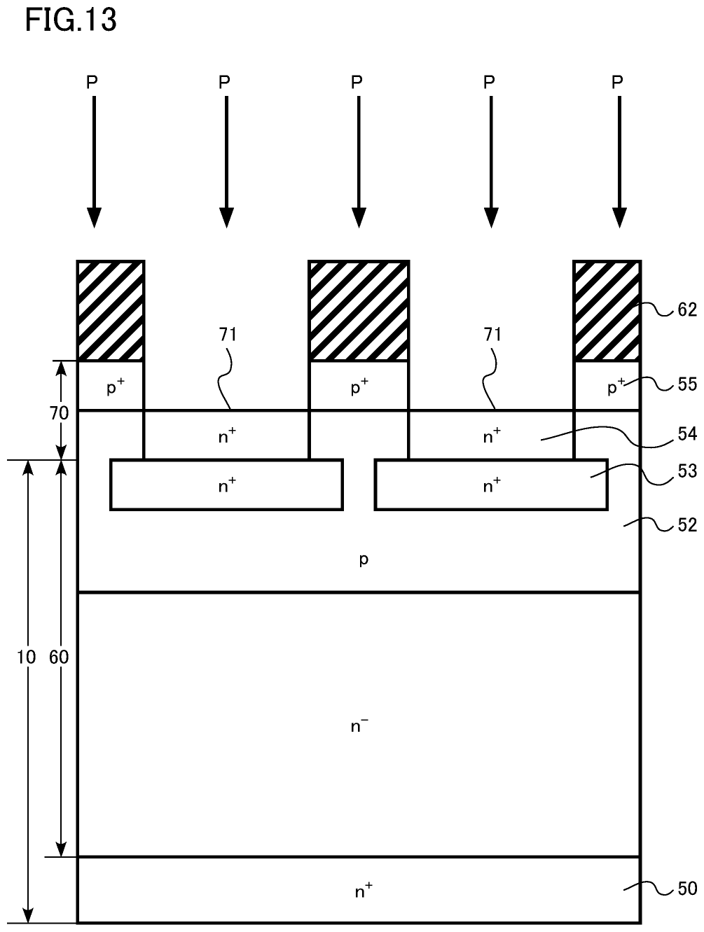

Then, by using the second mask material 62 as a mask, n-type impurities are ion-implanted into the second epitaxial layer 70 through the second opening 62a to form an n⁺-type upper source region 54 (FIG. 13). The upper source region 54 is an example of the third region. The upper source region 54 is in contact with the lower source region 53. The upper source region 54 is shallower than the lower source region 53. The n-type impurity is, for example, phosphorus (P) or nitrogen (N).

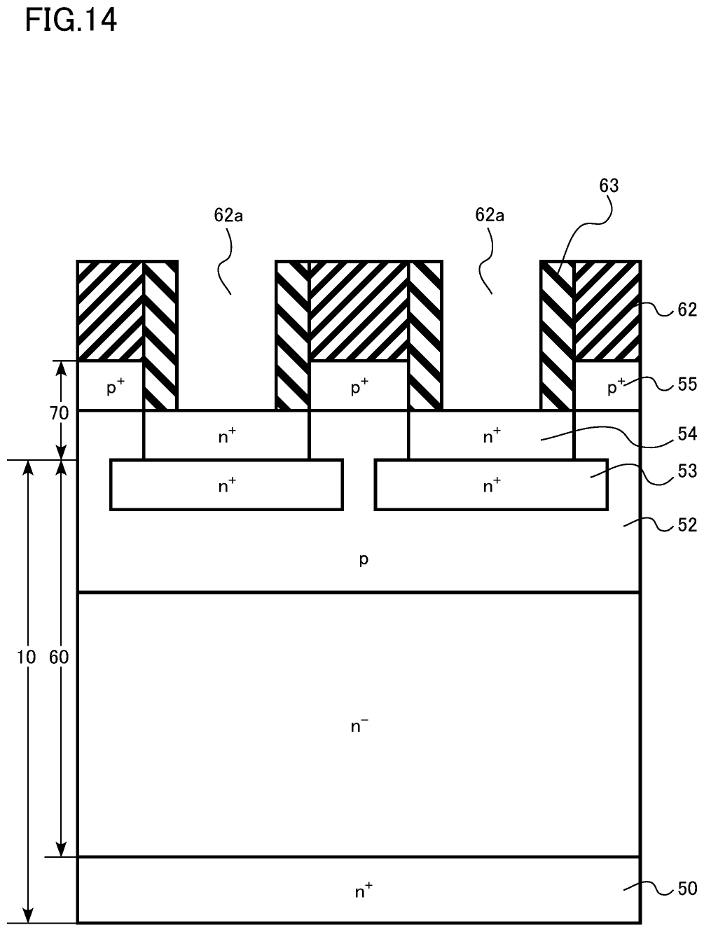

Then, a sidewall 63 is formed in the second opening 62a of the second mask material 62 (FIG. 14). The sidewall 63 is, for example, a silicon oxide film.

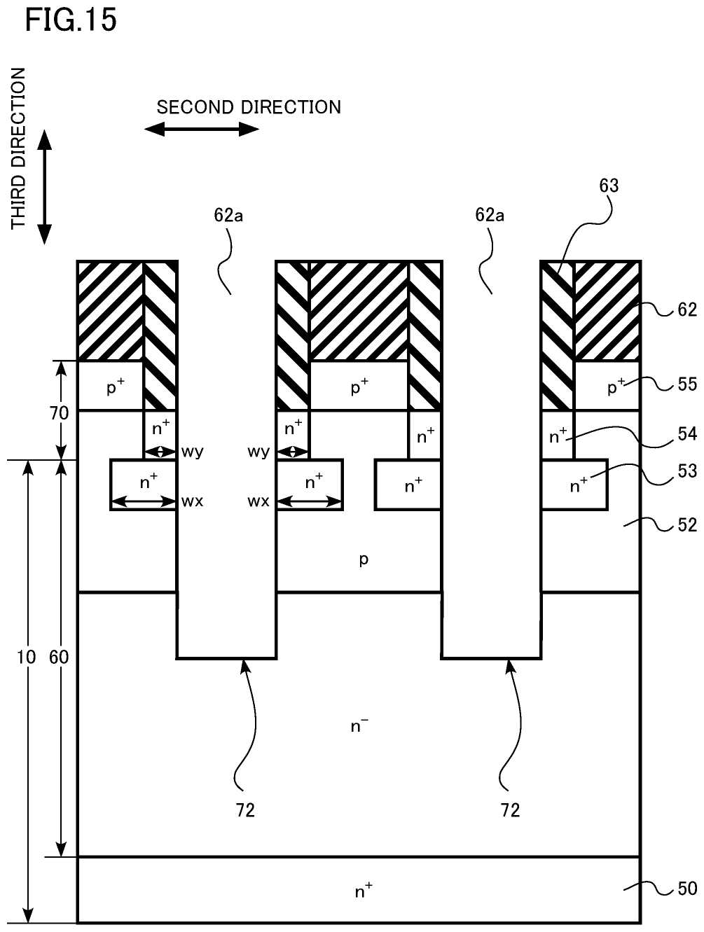

Then, a trench 72 is formed by using the second mask material 62 and the sidewall 63 as a mask (FIG. 15). The trench 72 penetrates the upper source region 54, the lower source region 53, and the body region 52. The trench 72 is formed by using, for example, an RIE method.

Each of the upper source region 54 and the lower source region 53 is divided into left and right regions by the trench 72. Each of the upper source region 54 and the lower source region 53 is divided into two regions with a trench interposed therebetween.

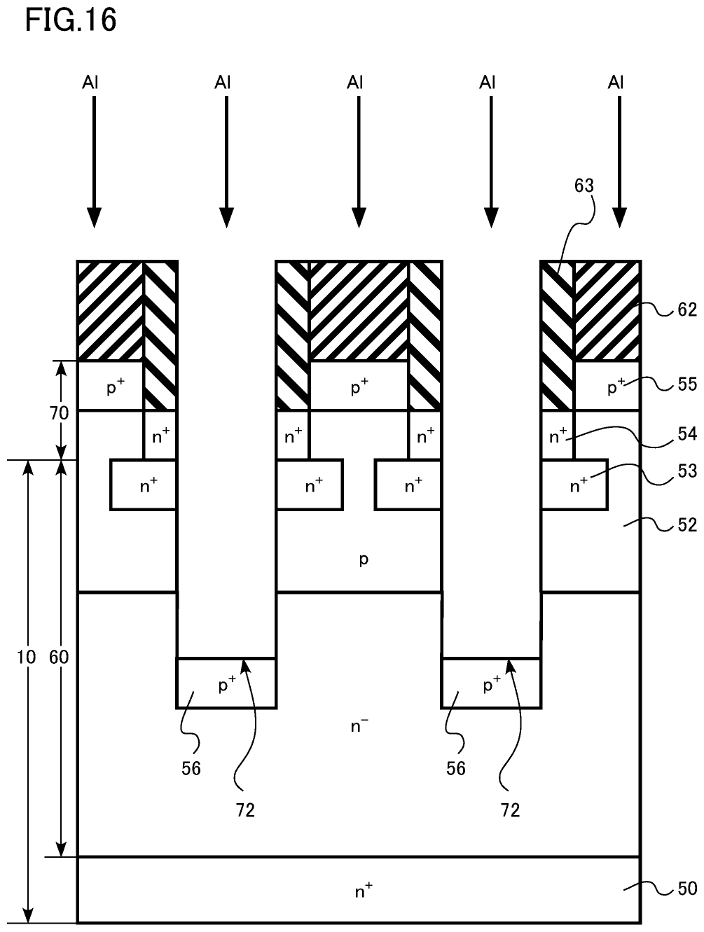

Then, by using the second mask material 62 and the sidewall 63 as a mask, p-type impurities are ion-implanted to form the p⁺-type electric field relaxation region 56 (FIG. 16). The electric field relaxation region 56 is formed at the bottom of the trench 72. The p-type impurity is, for example, aluminum (Al).

Then, the second mask material 62 and the sidewall 63 are removed. The second mask material 62 and the sidewall 63 are removed by using, for example, a wet etching method.

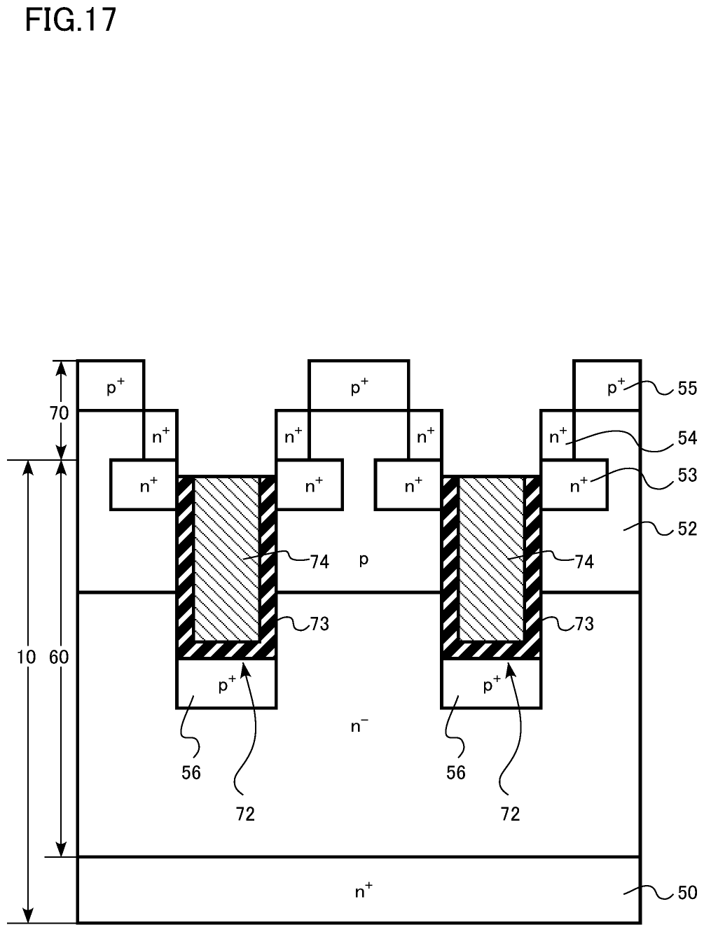

Then, a gate insulating layer 73 is formed in the trench 72. Then, a gate electrode 74 is formed on the gate insulating layer 73 in the trench 72 (FIG. 17). The upper surface of the gate electrode 74 is disposed in the trench 72.

The gate insulating layer 73 is, for example, a silicon oxide film. The gate electrode 74 is, for example, polycrystalline silicon containing p-type impurities or n-type impurities. The gate insulating layer 73 and the gate electrode 74 are formed by using, for example, a CVD method.

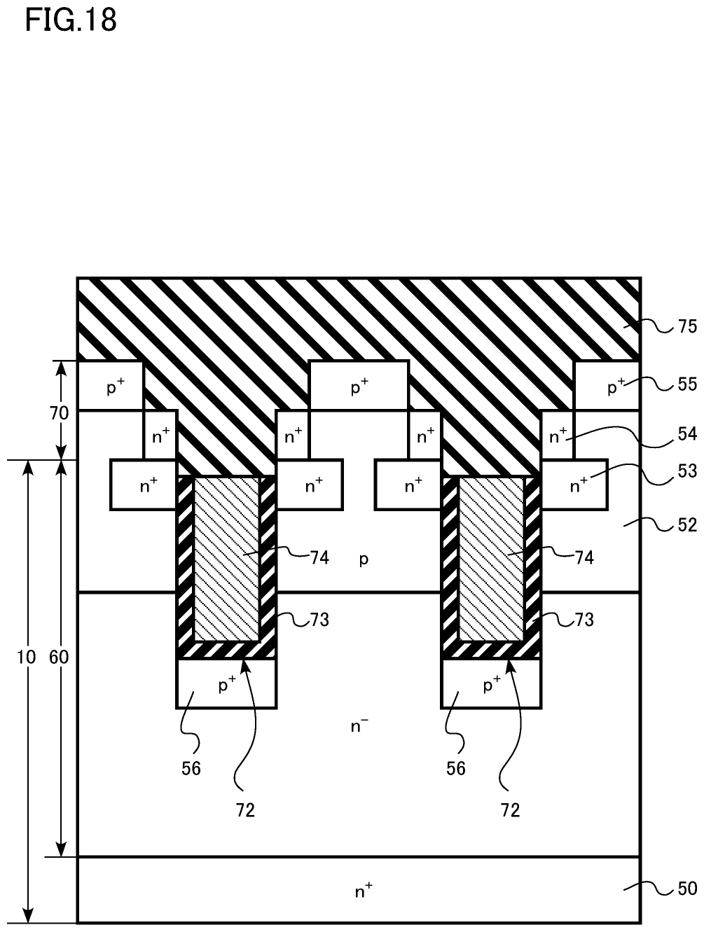

Then, the inside of the trench 72 is buried with a buried insulating layer 75 (FIG. 18). The buried insulating layer 75 is an example of an insulating layer. The buried insulating layer 75 is, for example, a silicon oxide film. The buried insulating layer 75 is formed by using, for example, a CVD method.

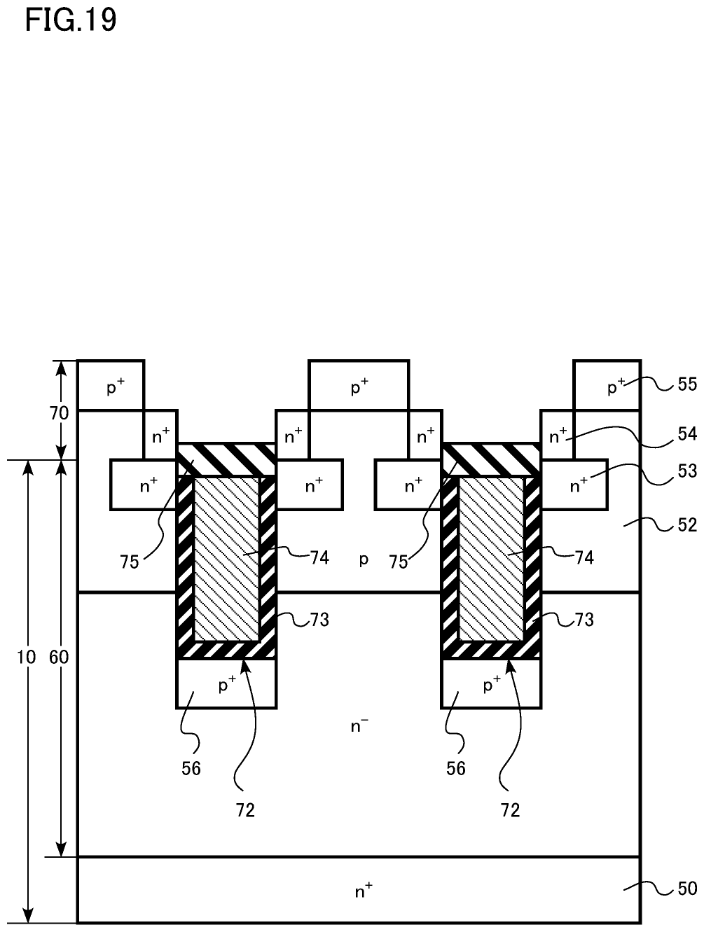

Then, the buried insulating layer 75 is etched so that at least a part of the side surface of the trench 72 is exposed (FIG. 19). For example, the upper source region 54 is exposed on the side surface of the trench 72.

Then, the source electrode 41 is formed. The source electrode 41 is formed in the trench 72 and on the upper surface of the second epitaxial layer 70. For example, the source electrode 41 is formed on the side surface of the trench 72 so as to be in contact with the upper source region 54. The source electrode 41 is formed by depositing a metal film by using a CVD method, for example.

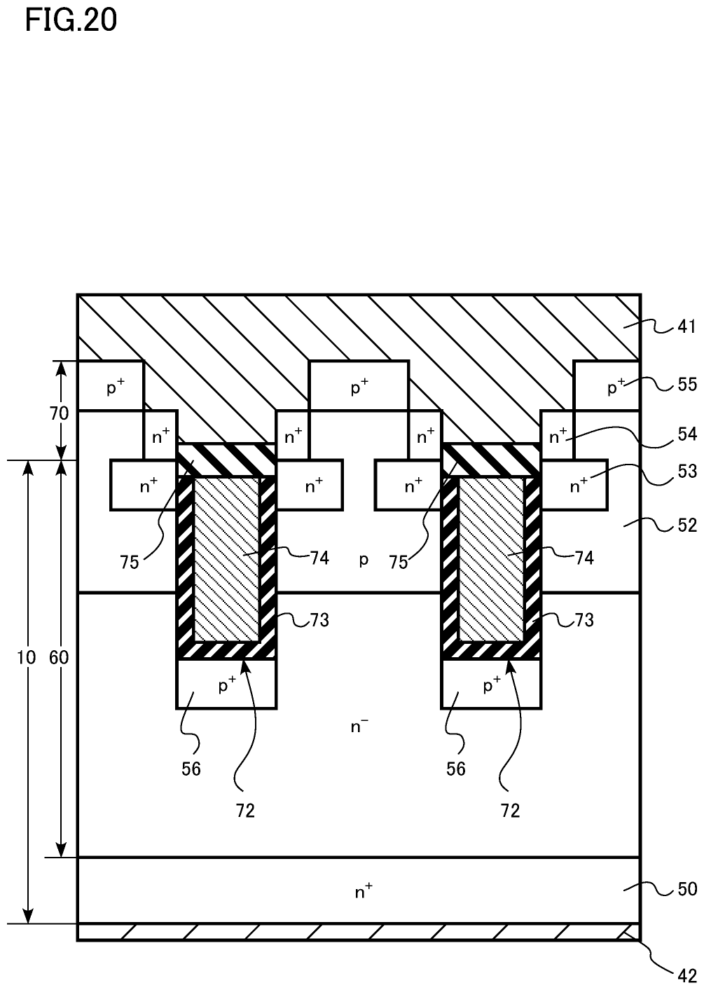

Then, a drain electrode 42 is formed on the back surface of the silicon carbide layer 10 by using a known process technique (FIG. 20).

By the manufacturing method described above, the MOSFET 100 shown in FIGS. 1 to 3 is manufactured.

Next, the function and effect of the semiconductor device according to the first embodiment will be described.

According to the MOSFET 100 of the first embodiment, it is possible to reduce the on-resistance and realize a high threshold voltage. The details will be described below.

A trench gate structure in which a gate electrode is provided in a trench is applied to the MOSFET 100. By applying the trench gate structure, the channel area per unit area is increased, and accordingly, the on-resistance of the MOSFET 100 is reduced.

In the MOSFET 100, the source electrode 41 is in contact with the upper source region 54 on the side surface of the first trench 11 and the side surface of the second trench 21. By realizing the contact of the source electrode 41 with the source region on the side surface of the trench, it is possible to reduce the distance between the trenches. Therefore, since the MOSFET 100 can be scaled down, the on-resistance of the MOSFET 100 is further reduced.

If the contact of the source electrode with the source region is provided on the side surface of the trench, it is necessary to increase the depth of the source region. The source region is formed by ion implantation of n-type impurities. In order to increase the depth of the source region, it is necessary to increase the accelerating voltage for ion implantation of n-type impurities. As the accelerating voltage for ion implantation increases, the extension of the hem of the n-type impurity profile in the depth direction increases.

In a MOSFET having a trench gate structure, if the hem of the n-type impurity profile of the source region in the depth direction extends long, the short channel effect of the MOSFET may increase and accordingly, the threshold voltage may be reduced. In addition, the short channel effect of the MOSFET may increase and accordingly, a variation in the threshold voltage may increase.

The MOSFET 100 has a two-layer structure in which a source region has the lower source region 53 and the upper source region 54. In the MOSFET 100, since a source region is formed in a two-layer structure, it is possible to suppress the accelerating voltage for ion implantation of n-type impurities as compared with a case where the source region is formed by one layer, for example. Therefore, it is possible to suppress the extension of the hem of the n-type impurity profile of the lower source region 53 in the depth direction.

Therefore, according to the MOSFET 100, the short channel effect is suppressed and accordingly, a high threshold voltage can be realized. In addition, since the short channel effect is suppressed, the variation in the threshold voltage is suppressed.

From the viewpoint of realizing a high threshold voltage, the standard deviation (ΔRp) of the profile of the hem on the body region 52 side in the depth-direction n-type impurity profile of a portion of the silicon carbide layer 10 including the lower source region 53 and the body region 52 is preferably equal to or less than 0.08 μm.

When the n-type impurity to be ion-implanted when forming the lower source region 53 of the MOSFET 100 is phosphorus (P), it is preferable to perform the ion implantation with an accelerating voltage equal to or less than 350 keV. In addition, when the n-type impurity to be ion-implanted is nitrogen (N), it is preferable to perform the ion implantation with an accelerating voltage equal to or less than 450 keV.

By limiting the accelerating voltage to the above range, in the depth-direction n-type impurity profile of the portion of the silicon carbide layer 10 including the lower source region 53 and the body region 52, the standard deviation (ΔRp) of the profile of the hem on the body region 52 side can be made to be equal to or less than 0.08 μm.

The second width (w2 in FIG. 3) of the first upper source region 54a in the second direction is smaller than the first width (w1 in FIG. 3) of the first lower source region 53a in the second direction. In other words, the first width (w1 in FIG. 3) of the first lower source region 53a in the second direction is larger than the second width (w2 in FIG. 3) of the first upper source region 54a in the second direction.

In addition, the fourth width of the second upper source region 54b in the second direction is smaller than the third width of the second lower source region 53b in the second direction. In other words, the third width of the second lower source region 53b in the second direction is larger than the fourth width of the second upper source region 54b in the second direction.

When forming the second mask material 62 in manufacturing the MOSFET 100 (see FIG. 11), the second mask material 62 may shift in the second direction with respect to the lower source region 53 due to misalignment in the lithography process. When the second mask material 62 shifts in the second direction with respect to the lower source region 53, one of the widths (wx in FIG. 15) of two regions of the lower source region 53, which is divided into the left and right regions by the trench 72, in the second direction may become smaller (see FIG. 15).

As the second-direction width of the lower source region 53 divided into the left and right regions by the trench 72 decreases, the parasitic resistance of the MOSFET 100 increases. Therefore, the on-resistance of the MOSFET 100 increases. In particular, if the second-direction width (wx in FIG. 15) of the lower source region 53 divided into the left and right regions by the trench 72 is smaller than the second-direction width (wy in FIG. 15) of the upper source region 54 divided into the left and right regions by the trench 72, the parasitic resistance of the MOSFET 100 increases and accordingly, the on-resistance of the MOSFET 100 increases.

If the second-direction width of the lower source region 53 divided into the left and right regions by the trench 72 becomes smaller, the parasitic resistance of the MOSFET 100 varies and accordingly, a variation in the on-resistance of the MOSFET 100 increases.

In the MOSFET 100, the width of the lower source region 53 in the second direction is larger than the width of the upper source region in the second direction. Therefore, even if the second mask material 62 shifts in the second direction with respect to the lower source region 53 due to misalignment in the lithography process, a reduction in the second-direction width (wx in FIG. 15) of the lower source region 53 divided into the left and right regions by the trench 72 is suppressed. Therefore, the on-resistance of the MOSFET 100 can be reduced. In addition, the variation in the on-resistance of the MOSFET 100 is suppressed.

From the viewpoint of reducing the on-resistance of the MOSFET 100, the difference between the first width (w1 in FIG. 3) of the first lower source region 53a in the second direction and the second width (w2 in FIG. 3) of the first upper source region 54a in the second direction is preferably equal to or more than 0.1 μm. In addition, the difference between the third width of the second lower source region 53b in the second direction and the fourth width of the second upper source region 54b in the second direction is preferably equal to or more than 0.1 μm.

From the viewpoint of reducing the on-resistance of the MOSFET 100, the width (w4 in FIG. 3) of the third region 54ax in the second direction is preferably smaller than the width (w3 in FIG. 3) of the first region 53ax in the second direction. In other words, the width (w3 in FIG. 3) of the first region 53ax in the second direction is preferably larger than the width (w4 in FIG. 3) of the third region 54ax in the second direction.

In addition, the width (w6 in FIG. 3) of the fourth region 54ay in the second direction is preferably smaller than the width (w5 in FIG. 3) of the second region 53ay in the second direction. In other words, the width (w5 in FIG. 3) of the second region 53ay in the second direction is preferably larger than the width (w6 in FIG. 3) of the fourth region 54ay in the second direction.

### Modification Example

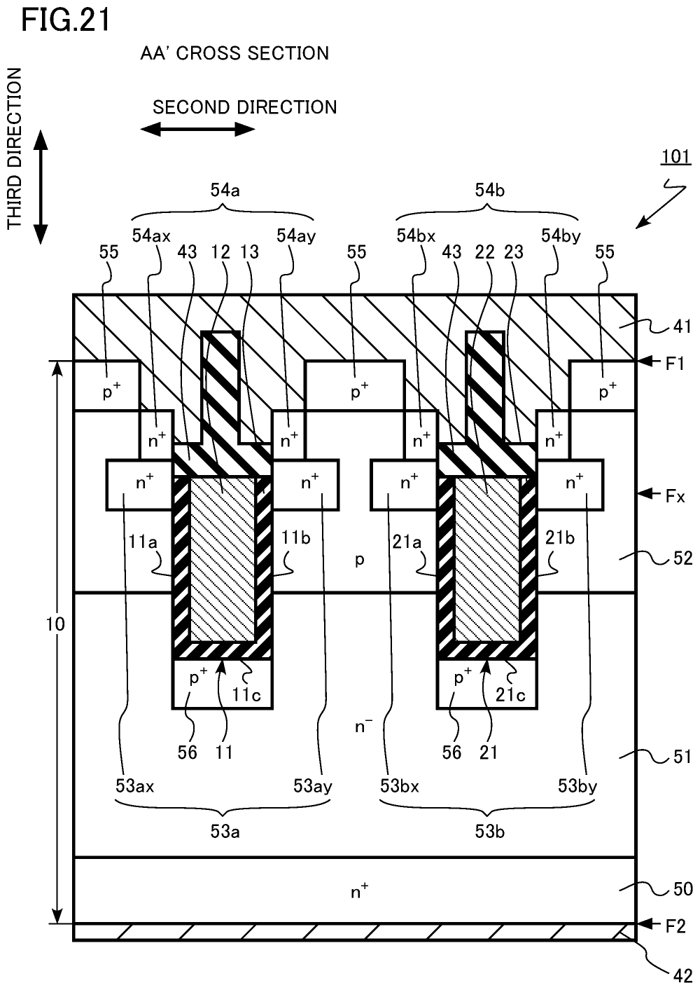

FIG. 21 is a schematic cross-sectional view of a semiconductor device of a modification example of the first embodiment. FIG. 21 is a diagram corresponding to FIG. 1 of the first embodiment.

A MOSFET 101 of the modification example is different from the MOSFET 100 according to the first embodiment in that a part of the interlayer insulating layer 43 is present above the first face F1 of the silicon carbide layer 10.

As described above, according to the MOSFETs of the first embodiment and the modification example, it is possible to reduce the on-resistance and realize a high threshold voltage.

### Second Embodiment

A semiconductor device according to a second embodiment is different from the semiconductor device according to the first embodiment in that a seventh silicon carbide region is provided between the third silicon carbide region and the fifth silicon carbide region. Hereinafter, the description of a part of the content overlapping the first embodiment may be omitted.

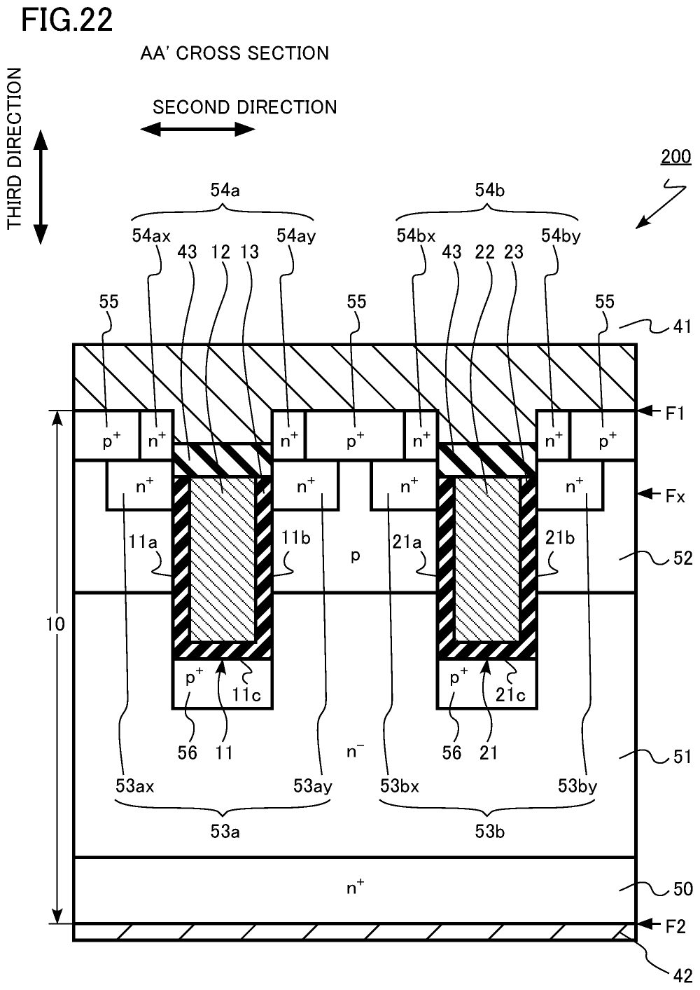

FIG. 22 is a schematic cross-sectional view of the semiconductor device according to the second embodiment. The semiconductor device according to the second embodiment is a trench gate type vertical MOSFET 200 using silicon carbide. The MOSFET 200 is an n-channel MOSFET having electrons as carriers.

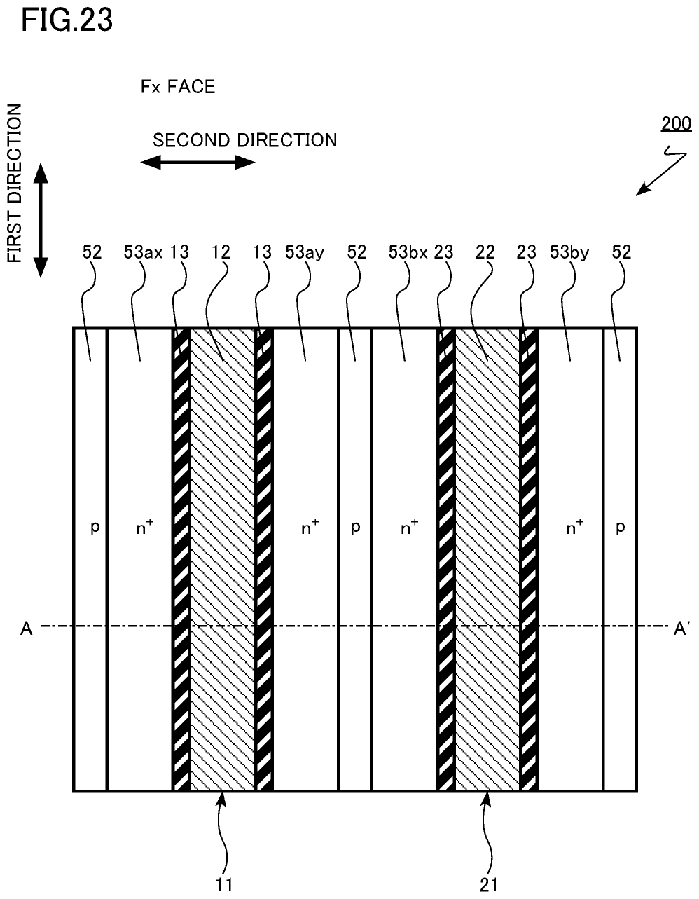

FIG. 23 is a schematic cross-sectional view of the semiconductor device according to the second embodiment. FIG. 23 is a cross-sectional view taken along the Fx face of FIG. 22. FIG. 22 is a cross-sectional view taken along the line AA′ of FIG. 23.

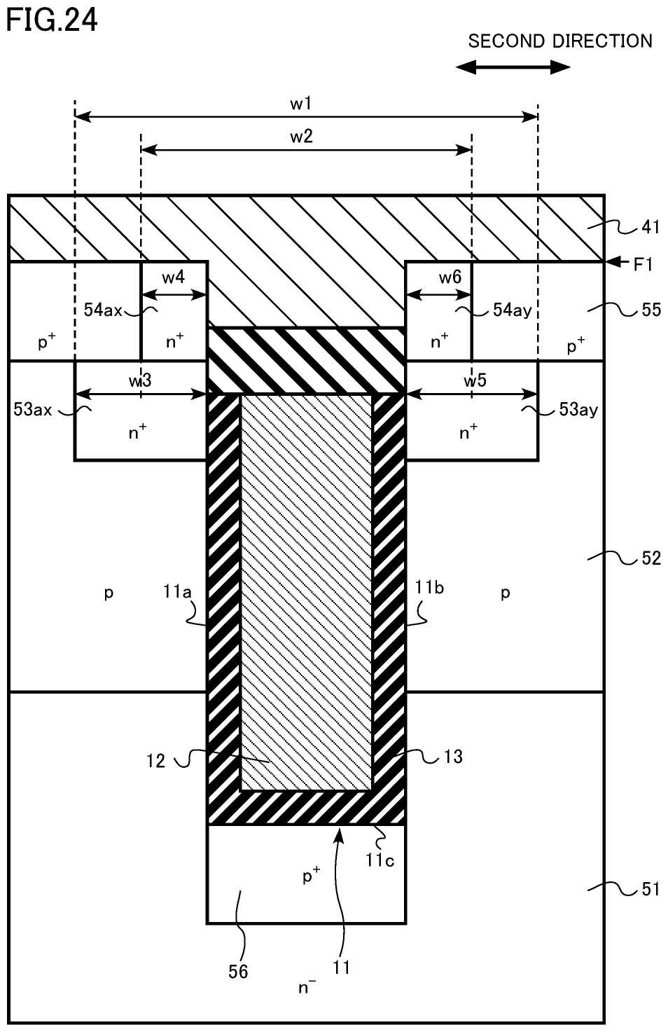

FIG. 24 is an enlarged schematic cross-sectional view of the semiconductor device according to the second embodiment. FIG. 24 is an enlarged view of a part of FIG. 22.

A MOSFET 200 includes a silicon carbide layer 10, a first trench 11, a first gate electrode 12, a first gate insulating layer 13, a second trench 21, a second gate electrode 22, a second gate insulating layer 23, a source electrode 41 (first electrode), a drain electrode 42 (second electrode), and an interlayer insulating layer 43.

Hereinafter, the first trench 11 and the second trench 21 may be collectively referred to as a trench. In addition, the first gate electrode 12 and the second gate electrode 22 may be collectively referred to as a gate electrode. In addition, the first gate insulating layer 13 and the second gate insulating layer 23 may be collectively referred to as a gate insulating layer.

In the silicon carbide layer 10, an n⁺-type drain region 50, an n⁻-type drift region 51 (first silicon carbide region), a p-type body region 52 (second silicon carbide region), a first lower source region 53a of n⁺-type (third silicon carbide region), a second lower source region 53b of n⁺-type (fifth silicon carbide region), a first upper source region 54a of n⁺-type (fourth silicon carbide region), a second upper source region 54b of n⁺-type (sixth silicon carbide region), a p⁺-type contact region 55 (seventh silicon carbide region), and a p⁺-type electric field relaxation region 56 are provided.

Hereinafter, the first lower source region 53a and the second lower source region 53b may be collectively referred to as a lower source region 53. In addition, the first upper source region 54a and the second upper source region 54b may be collectively referred to as an upper source region 54.

The p⁺-type contact region 55 is provided between the body region 52 and the surface of the silicon carbide layer 10. The contact region 55 is in contact with the source electrode 41.

The contact region 55 is provided between the first upper source region 54a and the second upper source region 54b. The contact region 55 is in contact with the first upper source region 54a. The contact region 55 is in contact with the second upper source region 54b.

The contact region 55 contains, for example, aluminum (Al) as a p-type impurity. The p-type impurity concentration in the contact region 55 is, for example, higher than the p-type impurity concentration in the body region 52.

The p-type impurity concentration in the contact region 55 is, for example, equal to or more than 1×10¹⁸ cm⁻³ and equal to or less than 1×10²¹ cm⁻³. In addition, the p-type impurity concentration in a portion of the contact region 55 in contact with the source electrode 41 is, for example, equal to or more than 1×10¹⁹ cm⁻³ and equal to or less than 1×10²¹ cm⁻³.

A method for manufacturing the semiconductor device according to the second embodiment is different from the method for manufacturing the semiconductor device according to the first embodiment in that a p-type fourth region is formed after forming a trench. Hereinafter, the description of a part of the content overlapping the method for manufacturing the semiconductor device according to the first embodiment may be omitted.

Next, an example of the method for manufacturing the semiconductor device according to the second embodiment will be described.

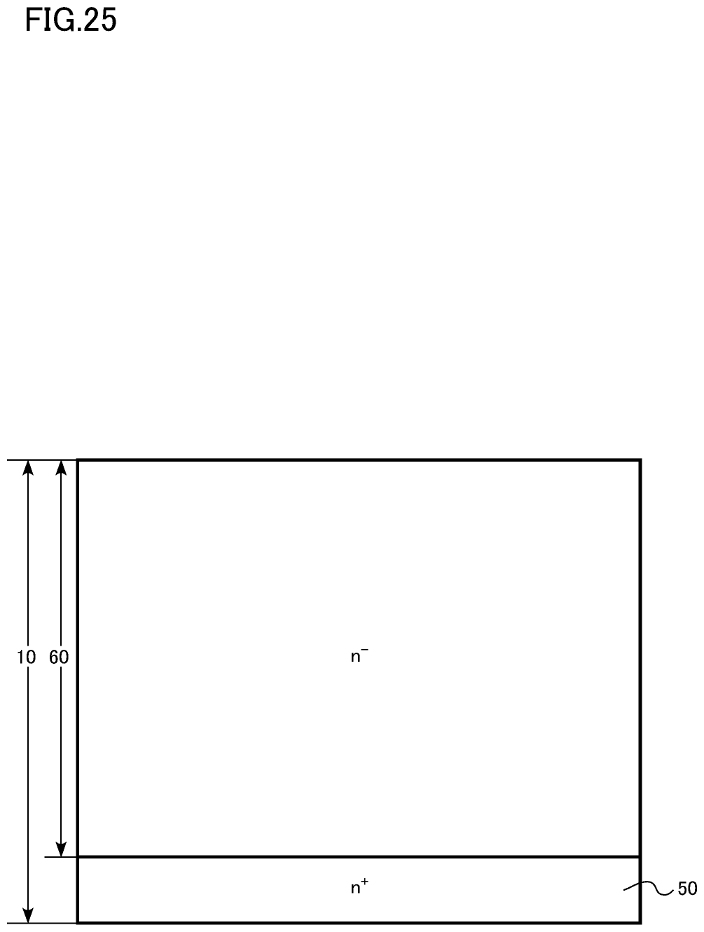

FIGS. 25 to 39 are schematic cross-sectional views showing an example of the method for manufacturing the semiconductor device according to the second embodiment. FIGS. 25 to 39 are cross-sectional views corresponding to FIG. 22.

First, the silicon carbide layer 10 having an n⁺-type drain region 50 and a first epitaxial layer 60 of n⁻-type formed on the drain region 50 by using an epitaxial growth method is prepared (FIG. 25). The first epitaxial layer 60 is an example of the first silicon carbide layer. A part of the first epitaxial layer 60 finally becomes the drift region 51.

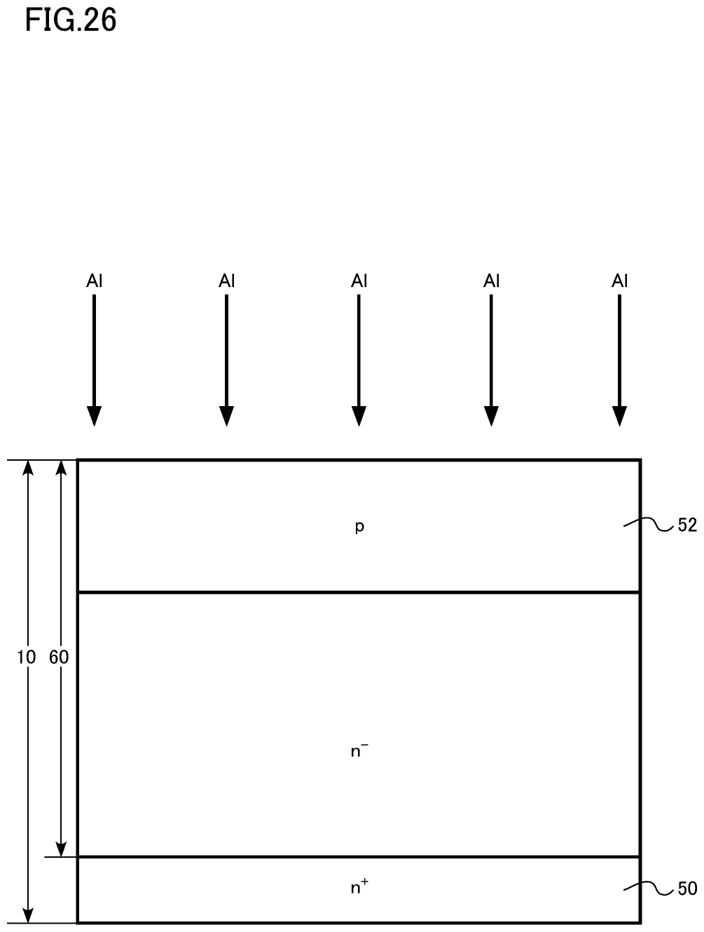

Then, p-type impurities are ion-implanted into the first epitaxial layer 60 to form the p-type body region 52 (FIG. 26). The body region 52 is an example of the first region. The p-type impurity is, for example, aluminum (Al). It is also possible to form the body region 52 by using the epitaxial growth method.

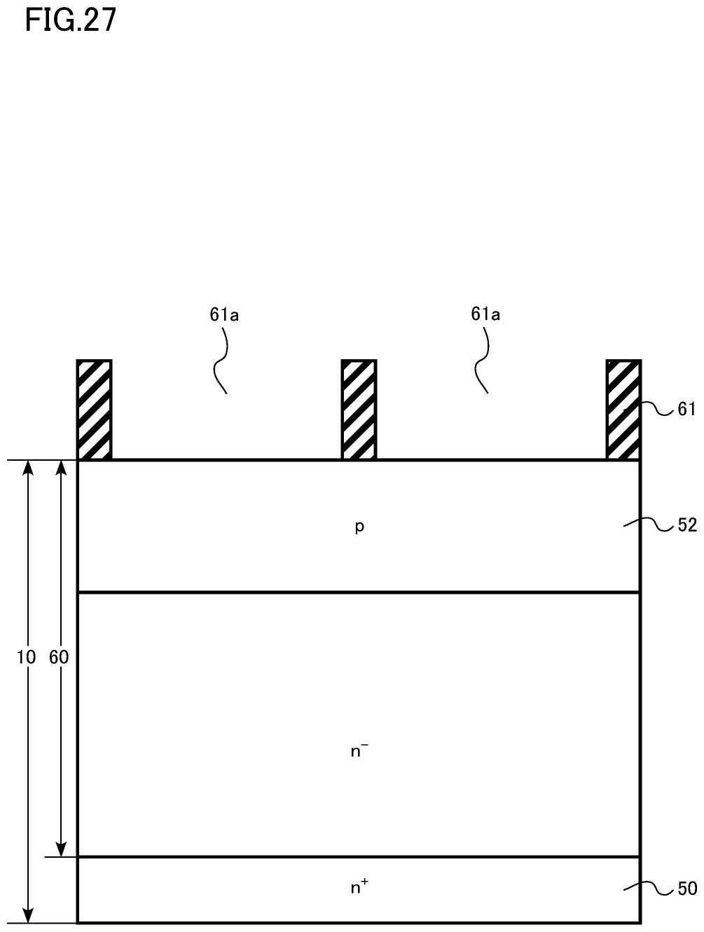

Then, a first mask material 61 is formed on the first epitaxial layer 60 (FIG. 27). The first mask material 61 has a first opening 61a. At the first opening 61a, the body region 52 is exposed.

For example, the first mask material 61 is formed by depositing a film by using a CVD method and patterning the film by using a lithography method and an RIE method. The first mask material 61 is, for example, a silicon oxide film.

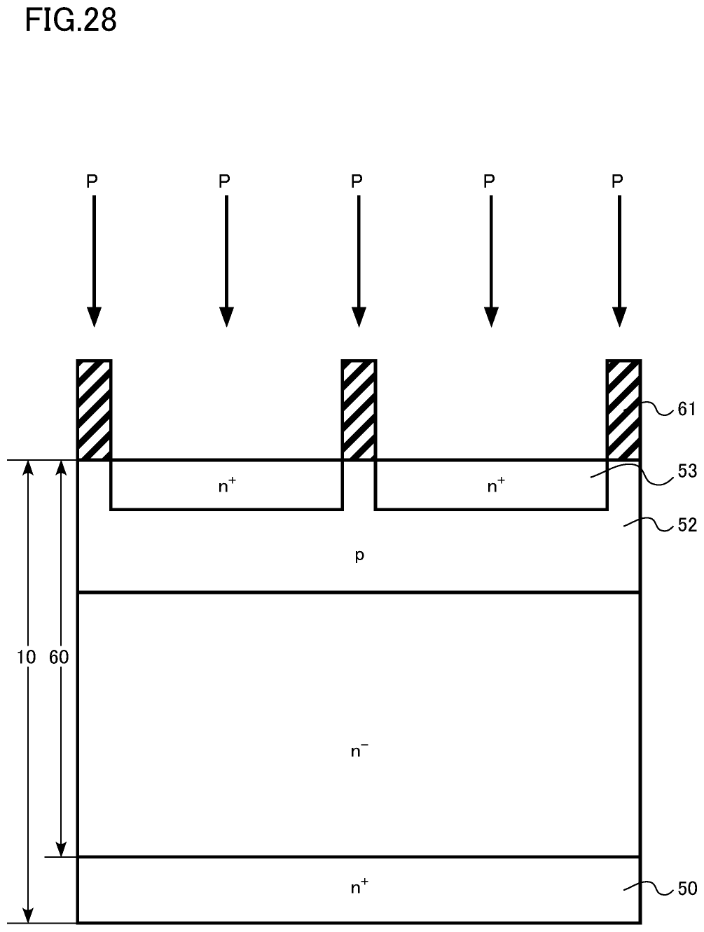

Then, by using the first mask material 61 as a mask, n-type impurities are ion-implanted into the body region 52 through the first opening 61a to form the n-′-type lower source region 53 (FIG. 28). The lower source region 53 is an example of the second region. The lower source region 53 is shallower than the body region 52. The n-type impurity is, for example, phosphorus (P) or nitrogen (N).

When the n-type impurity to be ion-implanted when forming the lower source region 53 is phosphorus (P), the ion implantation is performed with an accelerating voltage equal to or more than 100 keV and equal to or less than 350 keV, for example. In addition, when the n-type impurity to be ion-implanted is nitrogen (N), the ion implantation is performed with an accelerating voltage equal to or more than 100 keV and equal to or less than 450 keV, for example.

Then, the first mask material 61 is removed. The first mask material 61 is removed by using, for example, a wet etching method.

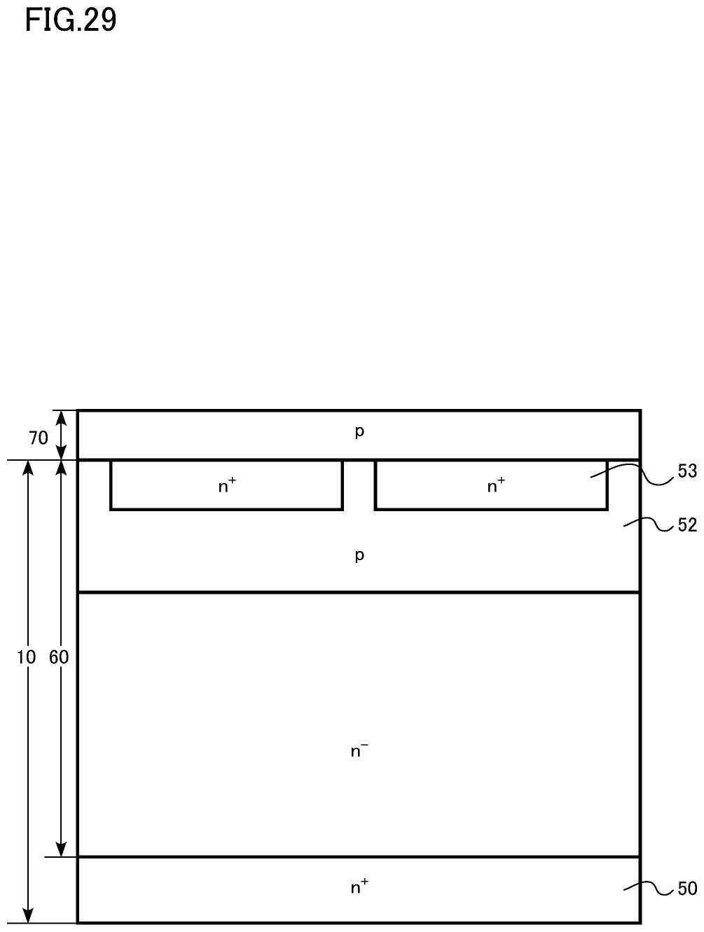

Then, a second epitaxial layer 70 of p-type is formed on the first epitaxial layer 60 by using an epitaxial growth method (FIG. 29). The second epitaxial layer 70 is an example of the second silicon carbide layer. For example, it is also possible to form a second epitaxial layer of p-type by forming an n-type epitaxial layer by using an epitaxial growth method and then ion-implanting p-type impurities.

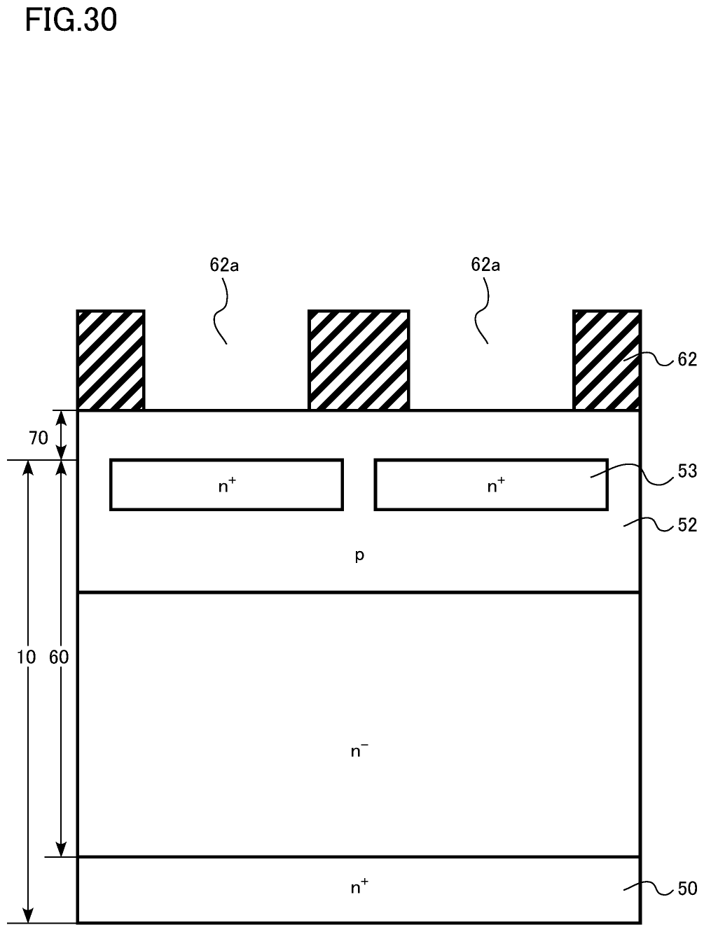

Then, a second mask material 62 is formed on the second epitaxial layer 70 (FIG. 30). The second mask material 62 has a second opening 62a. At the second opening 62a, the second epitaxial layer 70 above the lower source region 53 is exposed. The width of the second opening 62a in the second direction is smaller than the width of the lower source region 53 in the second direction.

For example, the second mask material 62 is formed by depositing a film by using a CVD method and patterning the film by using a lithography method and an RIE method. The second mask material 62 is, for example, a silicon oxide film.

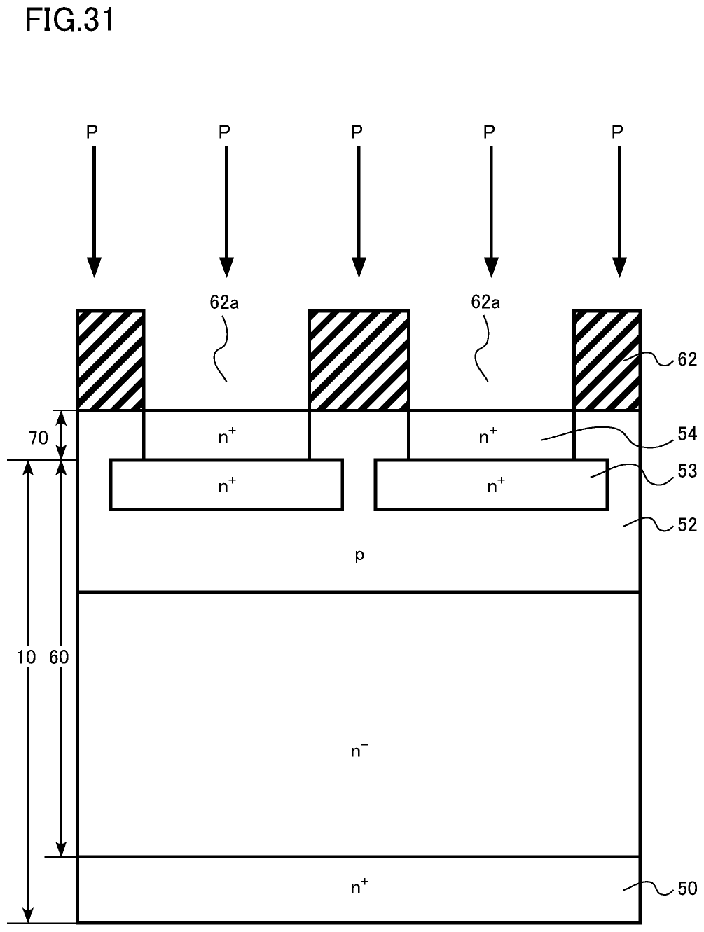

Then, by using the second mask material 62 as a mask, n-type impurities are ion-implanted into the second epitaxial layer 70 through the second opening 62a to form an n⁺-type upper source region 54 (FIG. 31). The upper source region 54 is an example of the third region. The upper source region 54 is in contact with the lower source region 53. The upper source region 54 is shallower than the lower source region 53. The n-type impurity is, for example, phosphorus (P) or nitrogen (N).

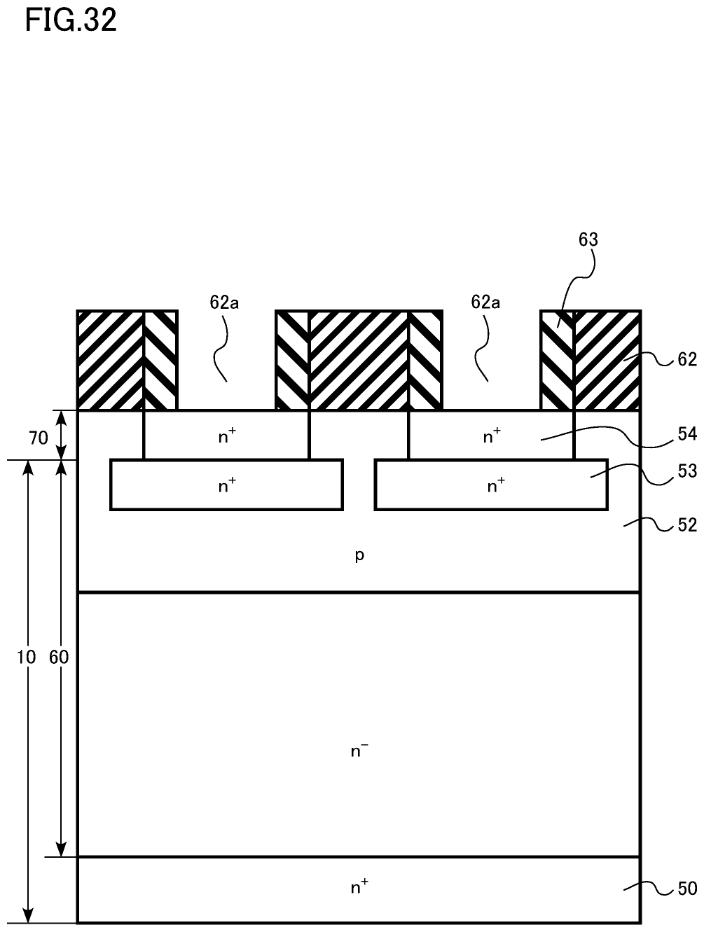

Then, a sidewall 63 is formed in the second opening 62a of the second mask material 62 (FIG. 32). The sidewall 63 is, for example, a silicon oxide film.

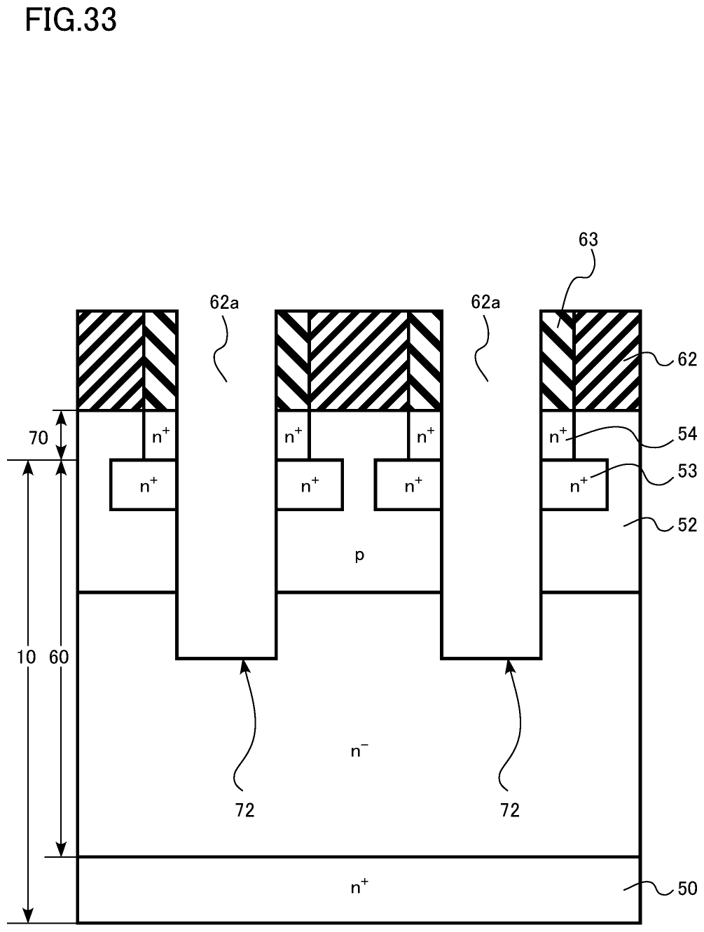

Then, a trench 72 is formed by using the second mask material 62 and the sidewall 63 as a mask (FIG. 33). The trench 72 penetrates the upper source region 54, the lower source region 53, and the body region 52. The trench 72 is formed by using, for example, an RIE method.

Each of the upper source region 54 and the lower source region 53 is divided into left and right regions by the trench 72. Each of the upper source region 54 and the lower source region 53 is divided into two regions with a trench interposed therebetween.

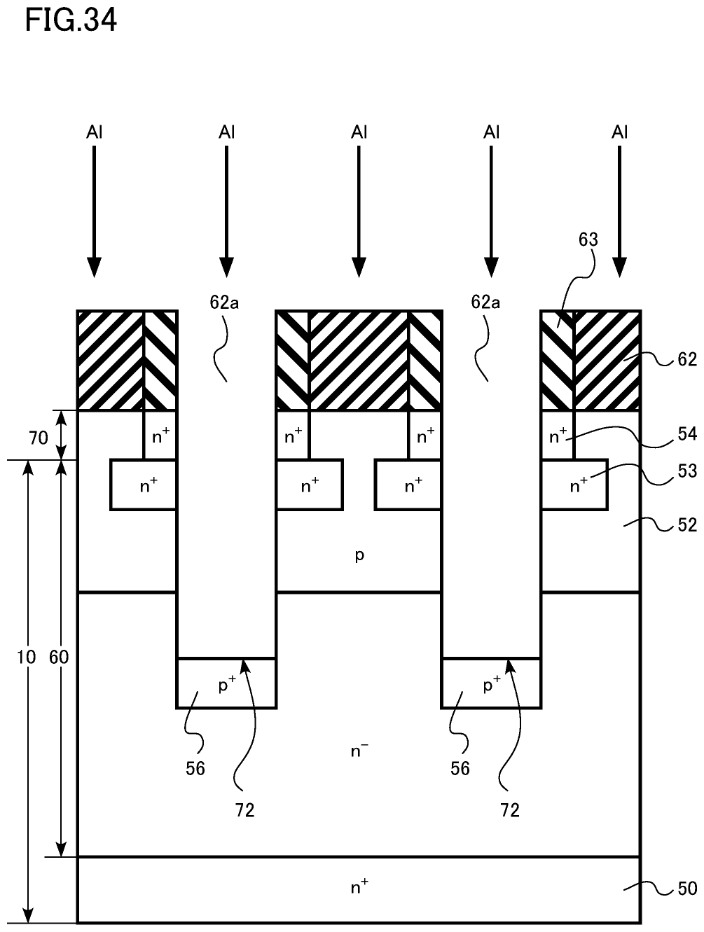

Then, by using the second mask material 62 and the sidewall 63 as a mask, p-type impurities are ion-implanted to form the p⁺-type electric field relaxation region 56 (FIG. 34). The electric field relaxation region 56 is formed at the bottom of the trench 72. The p-type impurity is, for example, aluminum (Al).

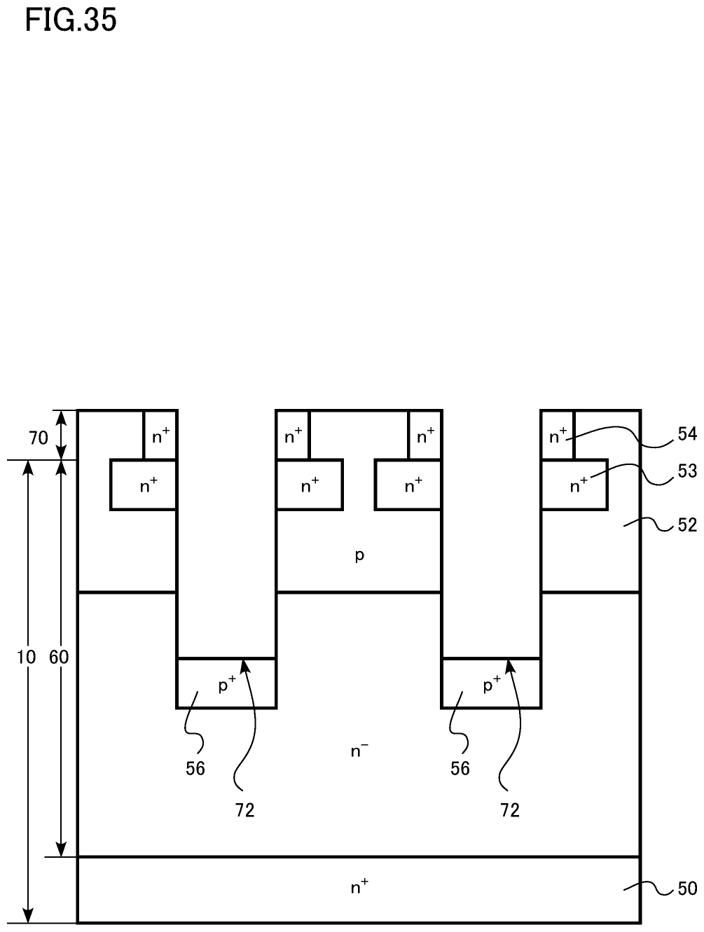

Then, the second mask material 62 and the sidewall 63 are removed. The second mask material 62 and the sidewall 63 are removed by using, for example, a wet etching method (FIG. 35).

Then, a third mask material 77 is formed in the trench 72 and on the second epitaxial layer 70.

For example, the third mask material 77 is formed by depositing a film by using a CVD method and patterning the film by using a lithography method and an RIE method. The third mask material 77 is, for example, a silicon oxide film.

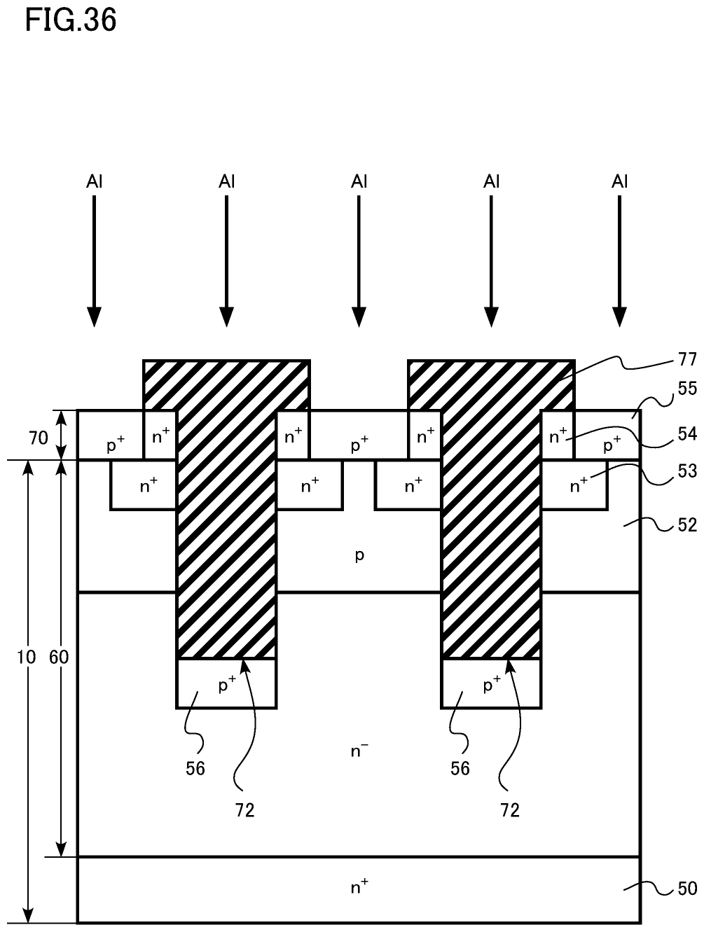

Then, by using the third mask material 77 as a mask, p-type impurities are ion-implanted into the second epitaxial layer 70 to form the p⁺-type contact region 55 (FIG. 36). The contact region 55 is an example of the fourth region. The p-type impurity is, for example, aluminum (Al).

Then, the third mask material 77 is removed. The third mask material 77 is removed by using, for example, a wet etching method.

Then, a gate insulating layer 73 is formed in the trench 72. Then, a gate electrode 74 is formed on the gate insulating layer 73 in the trench 72. The upper surface of the gate electrode 74 is disposed in the trench 72.

The gate insulating layer 73 is, for example, a silicon oxide film. The gate electrode 74 is, for example, polycrystalline silicon containing p-type impurities or n-type impurities. The gate insulating layer 73 and the gate electrode 74 are formed by using, for example, a CVD method.

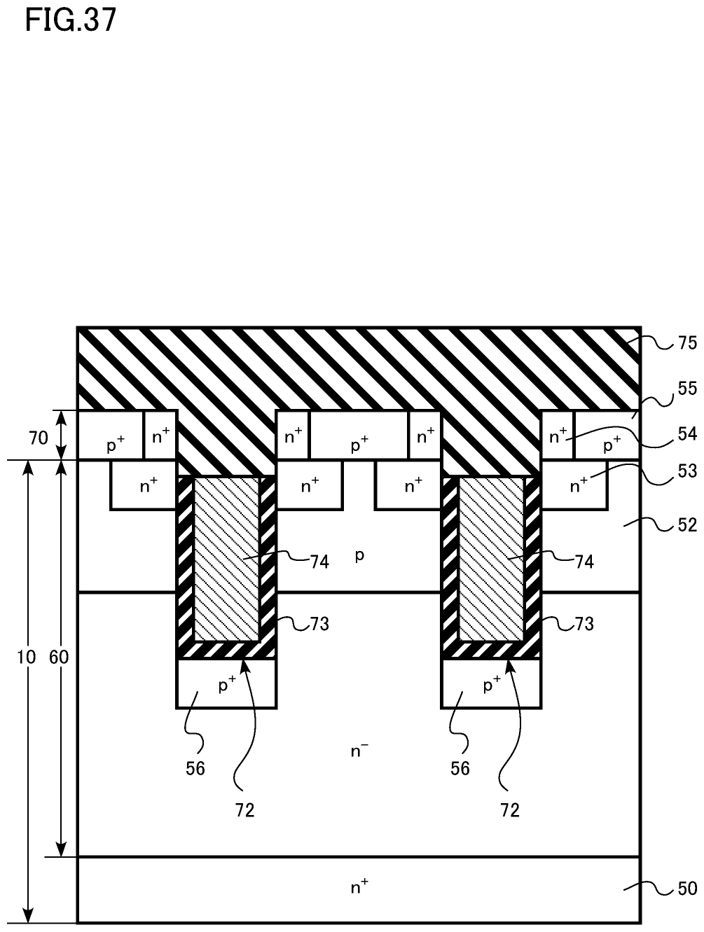

Then, the inside of the trench 72 is buried with a buried insulating layer 75 (FIG. 37). The buried insulating layer 75 is an example of an insulating layer. The buried insulating layer 75 is, for example, a silicon oxide film. The buried insulating layer 75 is formed by using, for example, a CVD method.

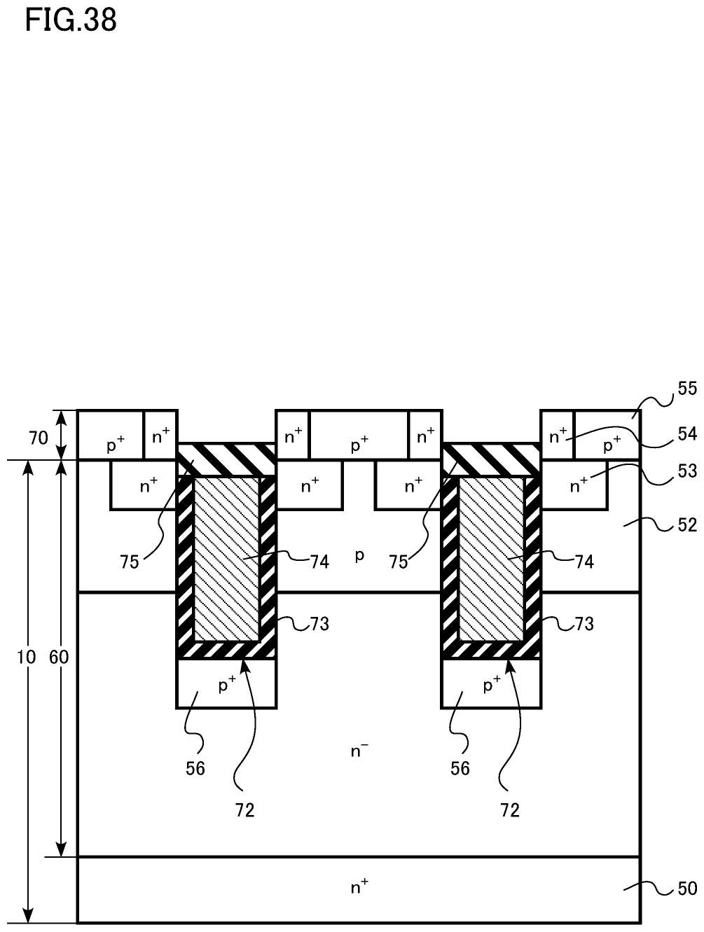

Then, the buried insulating layer 75 is etched so that at least a part of the side surface of the trench 72 is exposed (FIG. 38). The upper source region 54 is exposed on the side surface of the trench 72.

Then, a source electrode 41 is formed. The source electrode 41 is an example of an electrode. The source electrode 41 is formed in the trench 72 and on the upper surface of the second epitaxial layer 70. For example, the source electrode 41 is formed on the side surface of the trench 72 so as to be in contact with the upper source region 54. The source electrode 41 is formed by depositing a metal film by using a CVD method, for example.

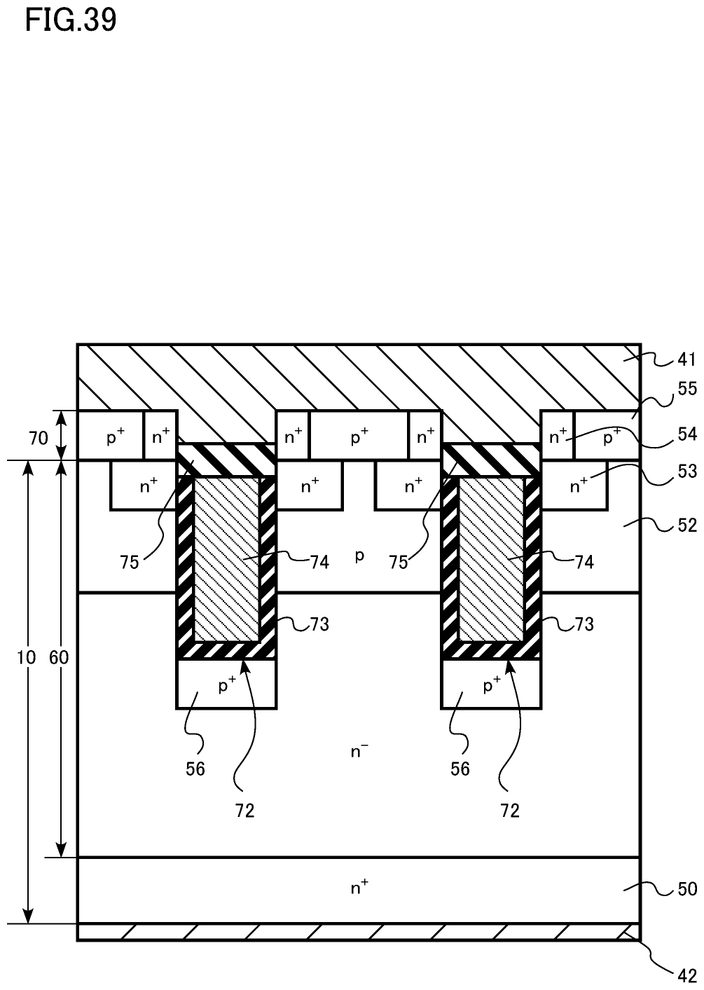

Then, a drain electrode 42 is formed on the back surface of the silicon carbide layer 10 by using a known process technique (FIG. 39).

By the manufacturing method described above, the MOSFET 200 shown in FIGS. 22 to 24 is manufactured.

The MOSFET 200 according to the second embodiment has the same function and effect as the MOSFET 100 according to the first embodiment. That is, since the MOSFET 200 can be scaled down, the on-resistance of the MOSFET 200 is reduced. In addition, since the short channel effect is suppressed, a high threshold voltage can be realized. In addition, since the short channel effect is suppressed, the variation in the threshold voltage is suppressed.

### Modification Example

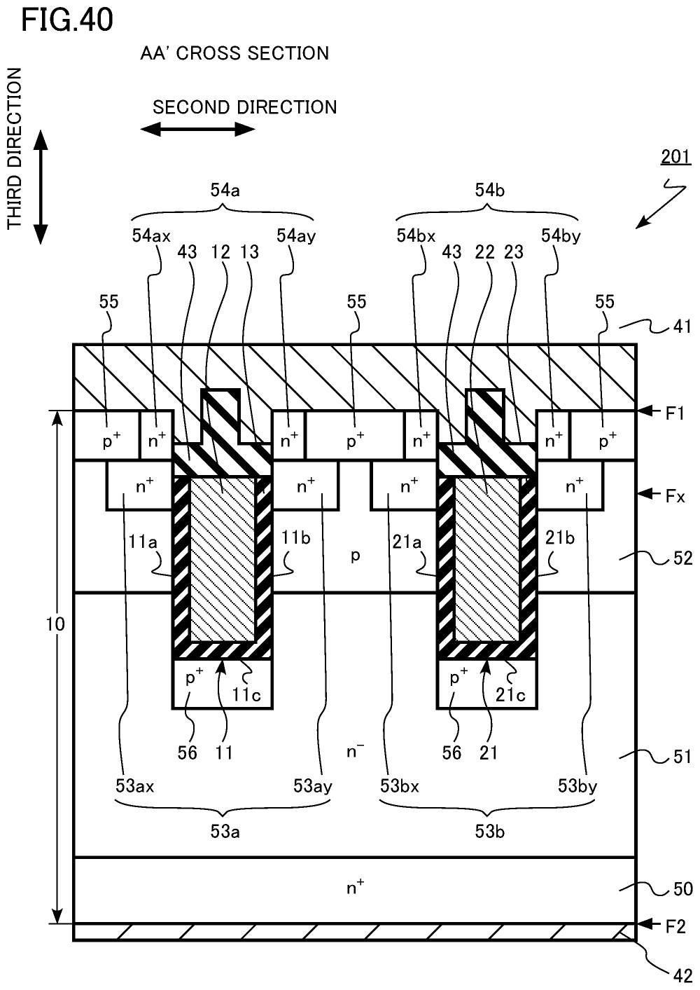

FIG. 40 is a schematic cross-sectional view of a semiconductor device of a modification example of the second embodiment. FIG. 40 is a diagram corresponding to FIG. 22 of the first embodiment.

A MOSFET 201 of the modification example is different from the MOSFET 200 according to the second embodiment in that a part of the interlayer insulating layer 43 is present above the first face F1 of the silicon carbide layer 10.

As described above, according to the MOSFETs of the second embodiment and the modification example, it is possible to reduce the on-resistance and realize a high threshold voltage.

### Third Embodiment

An inverter circuit and a drive device according to a third embodiment are an inverter circuit and a drive device each including the semiconductor device according to the first embodiment.

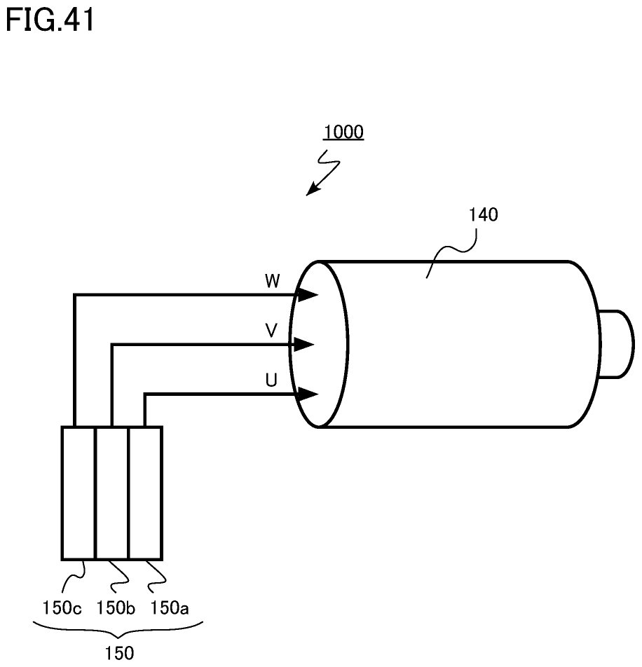

FIG. 41 is a schematic diagram of the drive device according to the third embodiment. A drive device 1000 includes a motor 140 and an inverter circuit 150.

The inverter circuit 150 includes three semiconductor modules 150a, 150b, and 150c having the MOSFET 100 according to the first embodiment as a switching element. By connecting the three semiconductor modules 150a, 150b, and 150c in parallel to each other, a three-phase inverter circuit 150 having three AC voltage output terminals U, V, and W is realized. The motor 140 is driven by the AC voltage output from the inverter circuit 150.

According to the third embodiment, the characteristics of the inverter circuit 150 and the drive device 1000 are improved by providing the MOSFET 100 with improved characteristics.

### Fourth Embodiment

A vehicle according to a fourth embodiment is a vehicle including the semiconductor device according to the first embodiment.

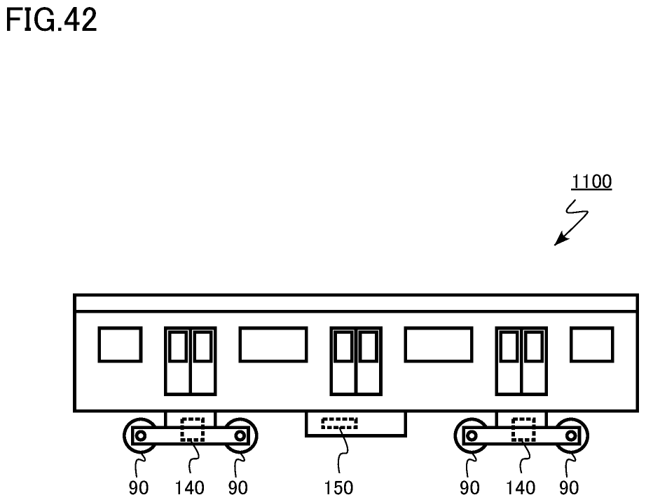

FIG. 42 is a schematic diagram of the vehicle according to the fourth embodiment. A vehicle 1100 according to the fourth embodiment is a railroad vehicle.

The vehicle 1100 includes a motor 140 and an inverter circuit 150.

The inverter circuit 150 includes three semiconductor modules having the MOSFET 100 according to the first embodiment as a switching element. By connecting the three semiconductor modules in parallel to each other, a three-phase inverter circuit 150 having three AC voltage output terminals U, V, and W is realized. The motor 140 is driven by the AC voltage output from the inverter circuit 150. The motor 140 rotates wheels 90 of the vehicle 1100.

According to the fourth embodiment, the characteristics of the vehicle 1100 are improved by providing the MOSFET 100 with improved characteristics.

### Fifth Embodiment

A vehicle according to a fifth embodiment is a vehicle including the semiconductor device according to the first embodiment.

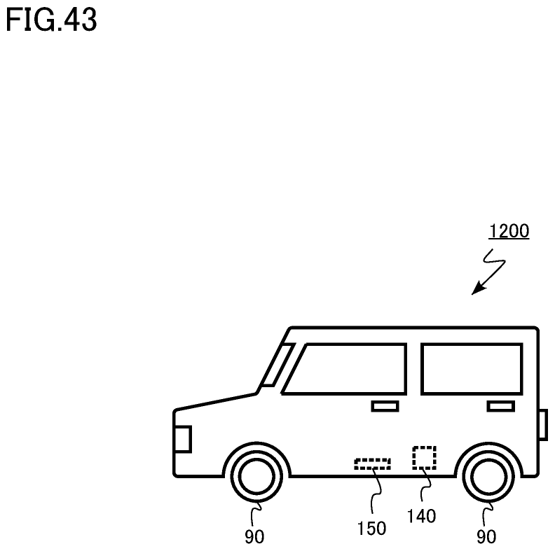

FIG. 43 is a schematic diagram of the vehicle according to the fifth embodiment. A vehicle 1200 according to the fifth embodiment is an automobile. The vehicle 1200 includes a motor 140 and an inverter circuit 150.

The inverter circuit 150 includes three semiconductor modules having the MOSFET 100 according to the first embodiment as a switching element. By connecting the three semiconductor modules in parallel to each other, a three-phase inverter circuit 150 having three AC voltage output terminals U, V, and W is realized.

The motor 140 is driven by the AC voltage output from the inverter circuit 150. The motor 140 rotates wheels 90 of the vehicle 1200.

According to the fifth embodiment, the characteristics of the vehicle 1200 are improved by providing the MOSFET 100 with improved characteristics.

### Sixth Embodiment

An elevator according to a sixth embodiment is an elevator including the semiconductor device according to the first embodiment.

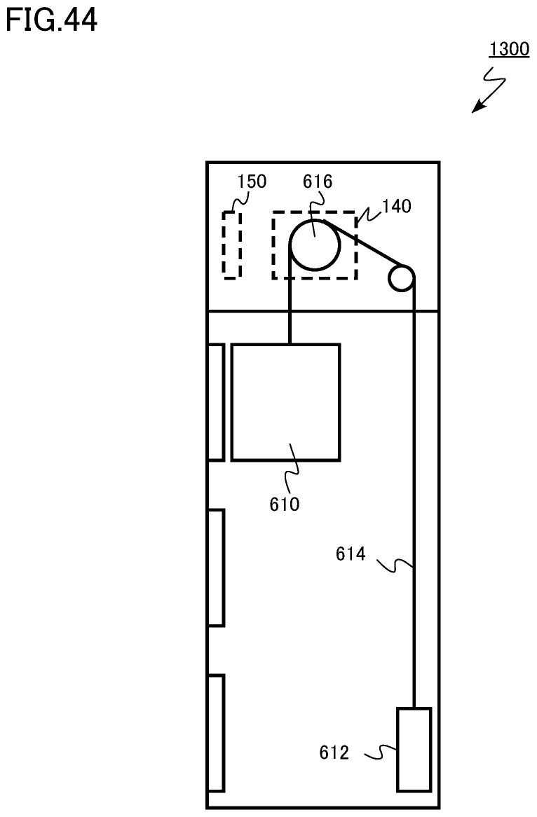

FIG. 44 is a schematic diagram of the elevator according to the sixth embodiment. An elevator 1300 according to the sixth embodiment includes a car 610, a counterweight 612, a wire rope 614, a hoisting machine 616, a motor 140, and an inverter circuit 150.

The inverter circuit 150 includes three semiconductor modules having the MOSFET 100 according to the first embodiment as a switching element. By connecting the three semiconductor modules in parallel to each other, a three-phase inverter circuit 150 having three AC voltage output terminals U, V, and W is realized.

The motor 140 is driven by the AC voltage output from the inverter circuit 150. The hoisting machine 616 is rotated by the motor 140, and the car 610 is moved up and down.

According to the sixth embodiment, the characteristics of the elevator 1300 are improved by providing the MOSFET 100 with improved characteristics.

In the first and second embodiments, the case of 4H-SiC has been described as an example of the crystal structure of silicon carbide. However, the embodiments can also be applied to silicon carbide having other crystal structures, such as 6H-SiC and 3C-SiC.

In the first and second embodiments, a MOSFET has been described as an example of the semiconductor device. However, embodiments can also be applied to an Insulated Gate Bipolar Transistor (IGBT). For example, the IGBT can be realized by replacing a region corresponding to the drain region 50 of the MOSFET 100 from the n type to the p type.

In addition, in the third to sixth embodiments, the cases where the semiconductor device according to the first embodiment is provided have been described as examples. However, the semiconductor device according to the second embodiment can also be applied.

In addition, in the third to sixth embodiments, the cases where the semiconductor devices of embodiments are applied to a vehicle or an elevator have been described as examples. However, the semiconductor devices of embodiments can also be applied to, for example, a power conditioner of a photovoltaic power generation system.

While certain embodiments have been described, these embodiments have been presented by way of example only, and are not intended to limit the scope of the inventions. Indeed, the semiconductor device, the semiconductor device manufacturing method, the inverter circuit, the drive device, the vehicle, and the elevator described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a silicon carbide layer having a first face parallel to a first direction and a second direction perpendicular to the first direction and a second face parallel to the first face;
a first trench disposed in the silicon carbide layer, disposed on a side of the first face of the silicon carbide layer, extending in the first direction, and having a first side surface and a second side surface;
a first gate electrode disposed in the first trench;
a first gate insulating layer disposed between the first gate electrode and the silicon carbide layer;
a first silicon carbide region of n-type disposed in the silicon carbide layer;
a second silicon carbide region of p-type disposed in the silicon carbide layer, disposed between the first silicon carbide region and the first face, and having a smaller depth from the first face than a depth of the first trench from the first face;
a third silicon carbide region of n-type disposed in the silicon carbide layer, disposed between the second silicon carbide region and the first face, and including a first region in contact with the first side surface and a second region in contact with the second side surface, a width of the third silicon carbide region in the second direction being a first width;
a fourth silicon carbide region of n-type disposed in the silicon carbide layer, disposed between the third silicon carbide region and the first face, and including a third region in contact with the first side surface and the first region and a fourth region in contact with the second side surface and the second region, a width of the fourth silicon carbide region in the second direction being a second width smaller than the first width;
a first electrode disposed on the side of the first face with respect to the silicon carbide layer and in contact with the fourth silicon carbide region;
a second electrode disposed on a side of the second face with respect to the silicon carbide layer; and
an interlayer insulating layer provided between the first gate electrode and the first electrode.

2. The semiconductor device according to claim 1,
wherein the first electrode is in contact with the first side surface and the second side surface.

3. The semiconductor device according to claim 1,
wherein a width of the third region in the second direction is smaller than a width of the first region in the second direction, and
a width of the fourth region in the second direction is smaller than a width of the second region in the second direction.

4. The semiconductor device according to claim 1,
wherein a difference between the first width and the second width is equal to or more than 0.1 μm.

5. The semiconductor device according to claim 1,
wherein, in an n-type impurity profile of a portion of the silicon carbide layer including the third silicon carbide region and the second silicon carbide region in a direction from the first face to the second face, a standard deviation of a profile of a hem on a side of the second silicon carbide region is equal to or less than 0.08 μm.

6. The semiconductor device according to claim 1,
wherein the third silicon carbide region contains nitrogen (N) or phosphorus (P).

7. The semiconductor device according to claim 1,
wherein at least a part of an interface between the interlayer insulating layer and the first electrode is disposed in the first trench.

8. The semiconductor device according to claim 1, further comprising:
a second trench disposed in the silicon carbide layer, disposed on the side of the first face of the silicon carbide layer, extending in the first direction, disposed in the second direction with respect to the first trench, and having a third side surface facing the second side surface and a fourth side surface;
a second gate electrode disposed in the second trench;
a second gate insulating layer disposed between the second gate electrode and the silicon carbide layer;
a fifth silicon carbide region of n-type disposed in the silicon carbide layer, disposed between the second silicon carbide region and the first face, and including a fifth region in contact with the third side surface and a sixth region in contact with the fourth side surface, a width of the fifth silicon carbide region in the second direction being a third width; and
a sixth silicon carbide region of n-type disposed in the silicon carbide layer, disposed between the fifth silicon carbide region and the first face, and including a seventh region in contact with the third side surface and the fifth region and an eighth region in contact with the fourth side surface and the sixth region, a width of the sixth silicon carbide region in the second direction being a fourth width smaller than the third width,
wherein the second silicon carbide region is disposed between the third silicon carbide region and the fifth silicon carbide region.

9. The semiconductor device according to claim 1, further comprising:
a seventh silicon carbide region of p-type disposed between the second silicon carbide region and the first face and having a p-type impurity concentration higher than a p-type impurity concentration in the second silicon carbide region,
wherein the first electrode is in contact with the seventh silicon carbide region.

10. An inverter circuit, comprising:
the semiconductor device according to claim 1.

11. A drive device, comprising:
the semiconductor device according to claim 1.

12. A vehicle, comprising:
the semiconductor device according to claim 1.

13. An elevator, comprising:
the semiconductor device according to claim 1.

14. A semiconductor device manufacturing method, comprising:
forming a first region of p-type by ion-implanting p-type impurities into a first silicon carbide layer of n-type;
forming a first mask material on the first silicon carbide layer, the first mask material having a first opening where the first region is exposed;
forming a second region of n-type having a smaller depth than the first region by ion-implanting n-type impurities into the first region through the first opening using the first mask material as a mask;
removing the first mask material;
forming a second silicon carbide layer of p-type on the first silicon carbide layer by using an epitaxial growth method;
forming a second mask material on the second silicon carbide layer, the second mask material having a second opening where the second silicon carbide layer above the second region is exposed;
forming a third region of n-type in contact with the second region by ion-implanting n-type impurities into the second silicon carbide layer through the second opening using the second mask material as a mask;
forming a sidewall in the second opening;
forming a trench penetrating the third region, the second region, and the first region using the second mask material and the sidewall as a mask;
forming a gate insulating layer in the trench; and
forming a gate electrode on the gate insulating layer in the trench so that an upper surface of the gate electrode is disposed in the trench.

15. The semiconductor device manufacturing method according to claim 14,
wherein the trench extends in a first direction parallel to a surface of the second silicon carbide layer, and
a width of the second opening in a second direction perpendicular to the first direction and parallel to the surface is smaller than a width of the second region in the second direction.

16. The semiconductor device manufacturing method according to claim 14, further comprising:
burying an inside of the trench above the gate electrode with an insulating layer after the forming the gate electrode;
etching the insulating layer so that at least a part of a side surface of the trench is exposed; and
forming an electrode in contact with the third region on the side surface of the trench.

17. The semiconductor device manufacturing method according to claim 14, further comprising:
forming a fourth region of p-type by ion-implanting p-type impurities into the second silicon carbide layer before the forming the second mask material; and
forming a recess penetrating the fourth region by using the second mask material as a mask before the forming the third region.

18. The semiconductor device manufacturing method according to claim 14,
wherein, when the n-type impurity to be ion-implanted in the forming the second region is phosphorus (P), ion implantation is performed with an accelerating voltage equal to or less than 350 keV, and when the n-type impurity to be ion-implanted in the forming the second region is nitrogen (N), ion implantation is performed with an accelerating voltage equal to or less than 450 keV.
